(19) United States
(12) Patent Application Publication
(10) Pub. No.: US 2026/0056057 A1
(43) Pub. Date: Feb. 26, 2026

(54) Fiber Optic Temperature Sensor System

(71) Applicant: Photon Control Inc., Richmond (CA)

(72) Inventors: Michael Tischler, Richmond (CA); Michael Feaver, Richmond (CA); Yoshua Ichihashi, Richmond (CA)

(73) Assignee: Photon Control Inc., Richmond (CA)

(21) Appl. No.: 19/371,870

(22) Filed: Oct. 28, 2025

Related U.S. Application Data
(63) Continuation-in-part of application No. 17/742,877, filed on May 12, 2022, now abandoned.
Application No. 17/742,877 is a continuation-in-part of application No. 16/901,951, filed on Jun. 15, 2020, now abandoned.
Application No. 16/901,951 is a continuation-in-part of application No. 16/442,420, filed on Jun. 14, 2019, now abandoned.

(51) Int. Cl. G01J 5/00; G01J 5/02; H01L 21/67

(52) U.S. Cl. CPC G01J 5/0007; G01J 5/0205; H01L 21/67248

(57) ABSTRACT

Embodiments of a temperature sensor system are disclosed. In one embodiment, the system includes a sensing element configured to be in thermal communication with a structural element of a semiconductor processing chamber, wherein the sensing element is configured to emit a return beam in response to a source beam emitted by a light source. The system further comprises an optical pathway spaced apart from the sensing element and where the optical pathway is configured to conduct the source beam to the sensing element and to conduct a portion of the return beam from the sensing element to a detector. A boundary is disposed between the optical pathway and the sensing element. The boundary is at least partially transparent to the source beam and to the return beam. The controller is configured to calculate a temperature of the sensing element based on at least one characteristic of the return beam.

### CROSS-REFERENCE TO RELATED APPLICATIONS

This application is a continuation-in-part of U.S. patent application Ser. No. 17/742,877 filed on May 12, 2022, which is a continuation-in-part of U.S. patent application Ser. No. 16/901,951 filed on Jun. 15, 2020, which is a continuation-in-part of U.S. patent application Ser. No. 16/442,420 filed on Jun. 14, 2019, the contents of all are incorporated herein by reference in their entirety.

### BACKGROUND

In semiconductor processing tools, there is a need for temperature control and monitoring to understand and maintain process control. A limited selection of materials can be used within chambers to avoid contamination of the chamber and degradation of the sensor materials exposed to the process environment. In addition, specific applications reach high temperatures and require materials to survive over, e.g., 300° C. Fiber optic temperature sensors used in such applications require careful material selection and unique design considerations. There is also a need for similar temperature sensing, monitoring, and control in other applications beyond semiconductor processing, such as, power, oil and gas, and medical, to name a few.

Fiber optic temperature sensors, such as temperature probes, normally include an optical fiber which can deliver light to a sensing material (e.g., phosphor). The light illuminates the phosphor which, in turn, luminesces visibly or in the near infrared.

The temperature of the phosphor can be determined by observing the changes in certain characteristics of the emitted light.

Like temperature sensors, thermographic phosphor sensors do not directly measure temperature but instead measure a physical property that exhibits strong temperature dependence, e.g., phosphorescence time decay. When this property is measured relative to a stable and accurate temperature source, the resulting relationship, or calibration curve can then be used to convert between the measured physical property, e.g., time decay, and temperature, enabling sensor functionality.

Phosphor material used inside temperature sensor probes are often exposed to harsh environments with high temperatures and corrosive chemicals. For example, such probes are often used in systems that use active heating and are exposed to radio frequency (RF) through, e.g., plasma generation, such as plasma deposition processes in a chamber. This results in a change or loss of measurement over time as the phosphor is attacked and degrades. The phosphor should be protected from the environment to ensure long term reliability of the temperature sensor measurement systems. The mechanical design of the probe considers protection of the phosphor from the environment containing at least plasma and fluorine at temperatures up to or above, e.g., 300° C.

Minimizing the difference in temperature between the phosphor and target surface enables more accurate measurement. For contact temperature sensors, this can be achieved by minimizing the heat loss from the contact tip to the body of the probe and maximizing the contact between the tip and the measurement surface.

A unique solution is required to achieve accurate contact temperature measurement at high temperatures in semiconductor process environments. To achieve this, the objective of the design often includes protecting the sensing material from the process environment, reducing the heat loss from the tip to improve contact measurement accuracy, and maximizing the material selection in the high temperature and semiconductor process environment.

Another challenge with temperature measurement is in implementing calibration of an electrostatic chuck (ESC) used to support a wafer to be etched or otherwise interacted with in the chamber. Solutions exist that use temperature sensors on the chuck, e.g., resistance temperature detectors (RTDs) glued to a wafer that is placed on the chuck. However, since RTDs need to be physically wired to the wafer, a feedthrough system is required, increasing the complexity of the chamber. Moreover, should one of the RTDs fail, the entire temperature sensing system would need to be changed. Furthermore, by increasing the number of RTDs used, the number of wires also increases, thus increasing the complexity further.

Another challenge is that environmental factors such as reactive gases, relative humidity, and pressure can adversely affect the sensing material (e.g., phosphor), impacting the sensing material's chemistry and microstructure.

Another challenge with temperature measurement is producing temperature measurement systems (e.g., probes) which have consistent performance between made systems. For example, some processes impose undesirable variability in the performance of the temperature measurement system that require calibration.

These issues make the setup of the temperature sensing system fragile, complex, and difficult to scale. While wireless options exist, these are found to be failure prone due to the electronics required. Another option that has been implemented uses radiometry or pyrometry, however, the readings in such a solution can be heavily influenced by the material it is measuring, which can introduce large offsets and limit accuracy.

### SUMMARY

The present disclosure pertains to a temperature sensor system having a sensing element configured to be in thermal communication with at least a portion of a structural element of a semiconductor processing chamber, wherein the sensing element is configured to emit a return beam in response to a source beam. The system further comprises a controller including a converter having a light source configured to emit the source beam and a detector configured to detect at least a portion of the at least one return beam. An optical pathway is provided, the optical pathway having a first end and a second end, wherein the first end is spaced apart from the sensing element and where the optical pathway is configured to conduct at least a portion of the source beam from the converter to the sensing element and to conduct at least a portion of the at least one return beam from the sensing element to the detector. At least one boundary is disposed between the first end of the optical pathway and the sensing element, the boundary comprising at least one of a gas, a solid, or a liquid, wherein the boundary is at least partially transparent to a portion of the at least one source beam and to a portion of the at least one return beam; and wherein the controller is configured to calculate a temperature of the sensing element based on at least one characteristic of the return beam.

The system further includes a probe having a first end and a second end, the first end opposite the second end, wherein at least a portion of the optical pathway is disposed within the probe and the first end of the probe shaft is spaced apart from the sensing element.

The characteristic of the return beam may include an intensity or amplitude, a change in intensity or amplitude over a time period, an intensity decay rate, a decay time constant, an optical power spectrum, and one or more portions of an optical power spectrum.

The controller is configured to modulate the source beam such that during a portion of a time the source beam is off, and to calculate a temperature of the sensing element based on the characteristic of the at least one return beam detected by the detector during at least a portion of the time when the source beam is off.

The structural element of the semiconductor processing chamber may include any of an edge ring, a shower head, and a chamber wall. The sensing element may be disposed at least partially in at least a portion of the structural element. The structural element may comprise a first recess and the sensing element is disposed at least partially within the first recess. The sensing element may be attached to the structural element with a bond, an adhesive, or a press-fit joint. The boundary may comprise an optical element, wherein the optical element comprises a lens to focus the beams emitted and received at the first end of the optical pathway.

The boundary may include a coating disposed on at least a portion of the sensing element, wherein the coating is at least partially transparent to a wavelength of the source beam and is at least partially transparent to a wavelength of the return beam. The boundary may also include a window disposed between the first end of the optical pathway and the sensing element, wherein the window is at least partially transparent to a wavelength of the source beam and is at least partially transparent to a wavelength of the return beam, wherein the window is attached to at least a portion of the structural element. The window may be hermetically sealed to at least a portion of the structural element. The window may be made from alumina, diamond, glass, sapphire, quartz, silica, silicon carbide, aluminum nitride, aluminum oxide, silicon nitride, or silicon.

At least a portion of the structural element may include a first recess and a second recess, wherein the first recess is disposed within the second recess and the sensing element is disposed at least partially within the first recess and the window is disposed at least partially within the second recess. The optical pathway may include an optical fiber, an optical waveguide, or an optical fiber bundle.

The boundary may also comprise a first portion and a second portion, wherein the first portion of the boundary is different from the second portion of the boundary and the first portion of the boundary comprises a free-space optical pathway and the second portion of the boundary comprises a solid, wherein the solid is at least partially transparent to a wavelength of the source beam and is at least partially transparent to a wavelength of the return beam. The solid may be made from diamond, glass, alumina, aluminum oxide, sapphire, quartz, silica, silicon, silicon carbide, or aluminum nitride.

### BRIEF DESCRIPTION OF THE FIGURES

The features of certain embodiments will become more apparent in the following detailed description in which reference is made to the appended figures wherein:

FIG. 1 is a schematic diagram of a fiber optic temperature sensor providing a gap between an optical fiber and a sensing element.

FIG. 2 is a schematic diagram of a fiber optic temperature sensor providing a gap between an optical fiber and a sensing element with the optical fiber being obliquely aligned with the sensing element.

FIG. 3 is a schematic diagram of a fiber optic temperature sensor providing a gap between an optical fiber and a sensing element with the optical fiber being aligned with a passage in an object between it and the sensing element.

FIG. 4 is a schematic diagram of a fiber optic temperature sensing system having multiple sensors with a gap between a respective optical fiber and a respective sensing element with the optical fibers being aligned with passages in an object between them and the sensing elements.

FIG. 5 is a schematic diagram of a fiber optic temperature probe providing a gap between a probe shaft containing an optical fiber and a sensing tip containing a sensing element.

FIG. 6 is a schematic diagram of a fiber optic temperature sensor for sensing the temperature of an object in a chamber, providing separation between an optical fiber outside of the chamber and a sensing element within the chamber.

FIG. 7 is a schematic diagram of a fiber optic temperature sensing system having multiple sensors with optical fibers aligned with passages through an ESC in a processing chamber.

FIG. 8 is a schematic diagram of a silicon wafer with a phosphor sensing element.

FIG. 9 is a schematic diagram of a system setup for the silicon wafer shown in FIG. 8.

FIG. 10 is a schematic illustration of the temperature probe, optical cable and temperature sensor converter.

FIG. 11 is a schematic illustration further depicting details of the interior components of the temperature sensor converter.

FIG. 12 is a cross-sectional top perspective view of the temperature probe.

FIG. 13 is a cross-sectional view of the temperature probe mounted to a showerhead of a semiconductor deposition chamber.

FIG. 14 is a cross sectional view of the tip.

FIG. 15 is a perspective view of the tip.

FIG. 16 is a cross sectional view of the tip showing an adhesive applied between the window and the body of the tip.

FIG. 17 is a schematic diagram of a fiber optic temperature sensor having encapsulated sensing material.

FIGS. 18A and 18B are each an image of an example encapsulated sensing material.

FIGS. 19A and 19B are, respectively, a top view and a cross sectional view of part of the example encapsulated sensing material of FIG. 18B.

FIGS. 20A and 20B are each a cross-sectional diagram of part of an example temperature probe.

FIG. 21A is a schematic diagram of an example fiber optic temperature sensor having an encapsulated sensing material.

FIG. 21B is a schematic diagram of an example mounted encapsulated sensing material.

FIG. 22 is a diagram of experimental results of the performance of example encapsulated sensing material.

FIG. 23 is a flow chart diagram of an example method of manufacturing an encapsulated sensing material.

FIG. 24 is another diagram of experimental results of the performance of encapsulated sensing material.

FIG. 25 is a diagram of a semiconductor process chamber.

FIGS. 26A to 26F are diagrams of a portion of a semiconductor process chamber.

FIGS. 27A to 27G are diagrams of configurations of remote sensor component.

FIGS. 28A to 28F are diagrams of configurations of a remote sensor component incorporated with a portion of a semiconductor process chamber.

### DETAILED DESCRIPTION

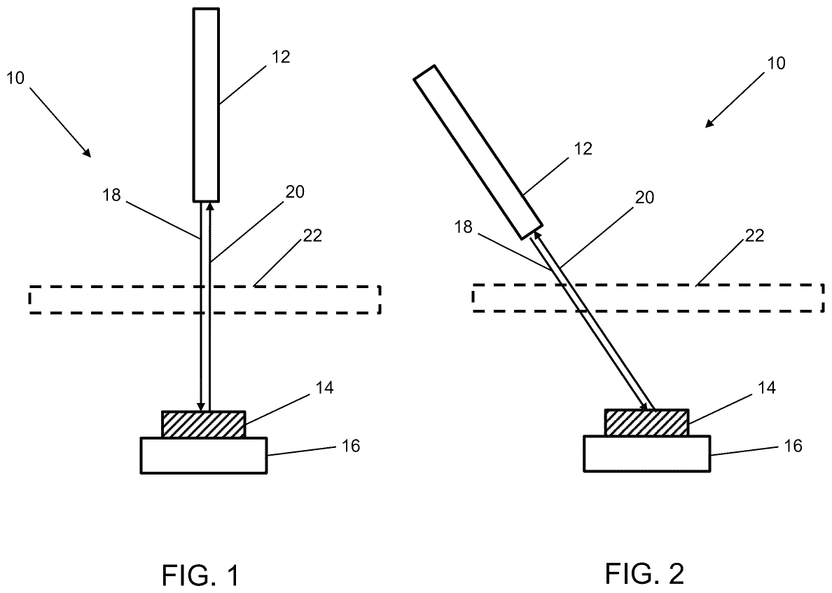

FIG. 1 illustrates a temperature sensor 10 that provides a separation between an optical fiber 12 used as the light source and a sensing element 14 that is used to measure the temperature of a measured object 16. The separation between the optical fiber 12 and the sensing element 14 can be implemented for various purposes as discussed below, for example, to thermally separate a probe tip from a probe shaft, to enable remote temperature sensing of a closed or separated environment such as a chamber, etc. As shown in FIG. 1, the optical fiber 12 can be positioned to direct a source beam 18 towards the sensing element 14 across a boundary 22, and detect at least one return beam 20 that has interacted with the sensing element 14 to measure the temperature of the measured object 16. The boundary 22 in this example is shown in dashed lines to illustrate that the boundary 22 can take the form of a physical boundary such as an optically transparent, partially transparent, or translucent “window” or passage, and/or may represent a gap between the optical fiber 12 and the sensing element 14 and any structural element(s) (not shown) that contain or support them. As discussed above, while examples herein may refer to temperature sensing, monitoring and control in semiconductor processing, the principles discussed herein can be applied to any application using such functionality.

FIG. 2 illustrates an alternative arrangement for the sensor 10 wherein the optical fiber 12 is aligned obliquely relative to the boundary 22 such that the beam 18 interacts with the sensing element 14 at an angle. The arrangement shown in FIG. 2 can allow the sensor 10 to be deployed in various applications where straight-line separation is not possible or is difficult. Moreover, the oblique arrangement can be used when the supporting element(s) provide constraints making a straight-line arrangement difficult.

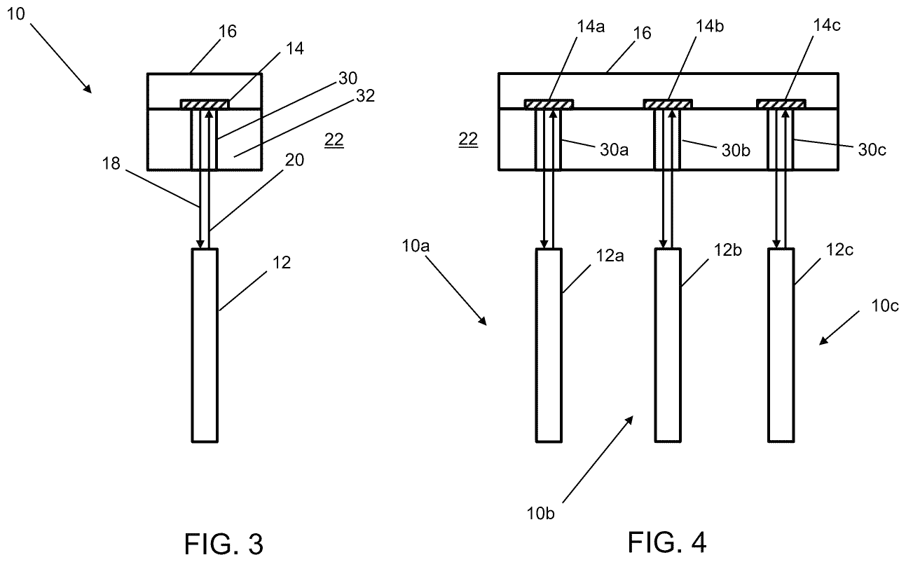

FIGS. 3 and 4 illustrate other forms the boundary 22 may take, namely in which the optical fiber 12 is aligned with a passage 30 in a structural element 32 which is interposed between the optical fiber 12 and the sensing element 14. The arrangement shown in FIGS. 3 and 4 can be implemented in scenarios where temperature sensing is performed from below the measured object 16, e.g., within a plasma chamber. It can be appreciated that this arrangement can also be implemented from above the sensing element 14 and measurement object 16. Moreover, it can be appreciated that while the optical fiber 12 is shown to be positioned at a distance from the passage 30, the optical fiber 12 can also be inserted into the passage 30 or otherwise embedded or secured in the structural element 32.

In FIG. 4, it can be seen that multiple sensors 10a, 10b, 10c (three shown for illustrative purposes only) can be integrated into a temperature measurement system. In this example, a first optical fiber 12a remotely interacts with a first sensing element 14a, and second and third optical fibers 12b, 12c remotely interact with second and third sensing elements 14b, 14c via first, second and third passages 30a, 30b, 30c for measuring at multiple points on the measured object 16. It can be appreciated that this multiple sensor arrangement can also be implemented with the configurations shown in FIGS. 1 and 2. It can also be appreciated that the multiple sensor arrangement can be used to measure multiple measured objects (not shown).

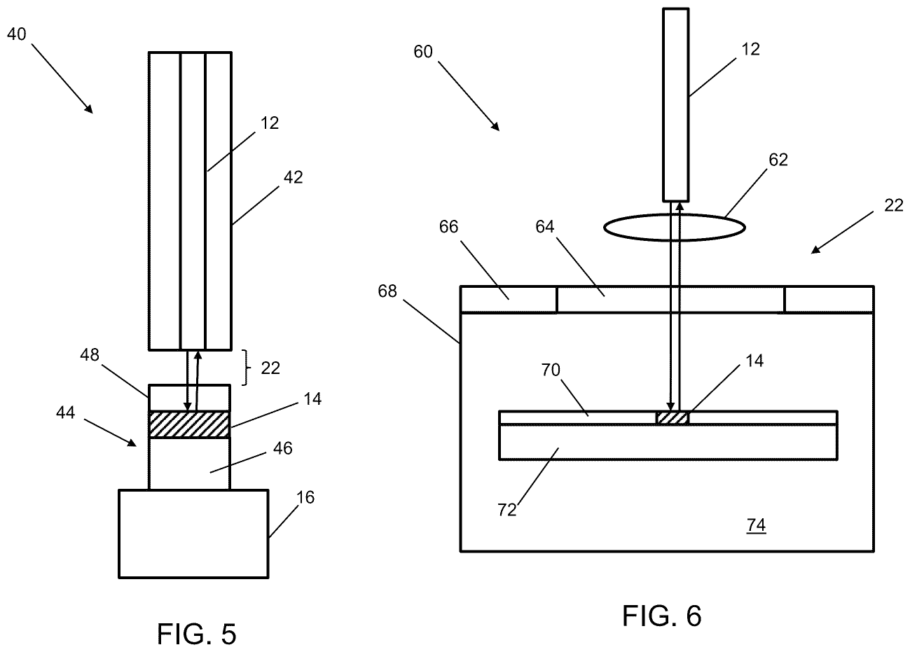

FIG. 5 shows an example embodiment of a temperature sensing probe 40. In this example, the boundary 22 takes the form of a gap between a probe shaft 42 containing the optical fiber 12 and a probe tip 44 that includes an object engaging portion 46, sometimes referred to as a “button”, with a sensing element 14. The sensing element 14 engages the object engaging portion 46 to detect the temperature of the measured object 16. The boundary 22 also includes a window 48 that is used to protect the sensing element 14 in the tip 44.

FIG. 6 illustrates a temperature sensing system 60 for a semiconductor processing chamber 68, wherein the boundary 22 includes a transparent window 64 in a lid 66 of the chamber 68. The optical fiber 12 is positioned outside of the chamber 68 and is aligned with the window 64 to enable the source beam 18 to reach the sensing element 14 that is on or integrated with a silicon wafer 70 supported by an ESC 72. It can be appreciated that details of the interior 74 of the chamber 68 are omitted for ease of illustration. It can also be appreciated that multiple sensing elements 14 and multiple optical fibers 12 can be included in an arrangement such as that shown in FIG. 6, with either a sufficiently wide window 64 or multiple windows 64 in the lid 66 (not shown). Also shown in FIG. 6 is a lens 62 (or lens device or system) that can be used to focus the beam 18 in applications where the distance between the optical fiber 12 and the sensing element 14 requires.

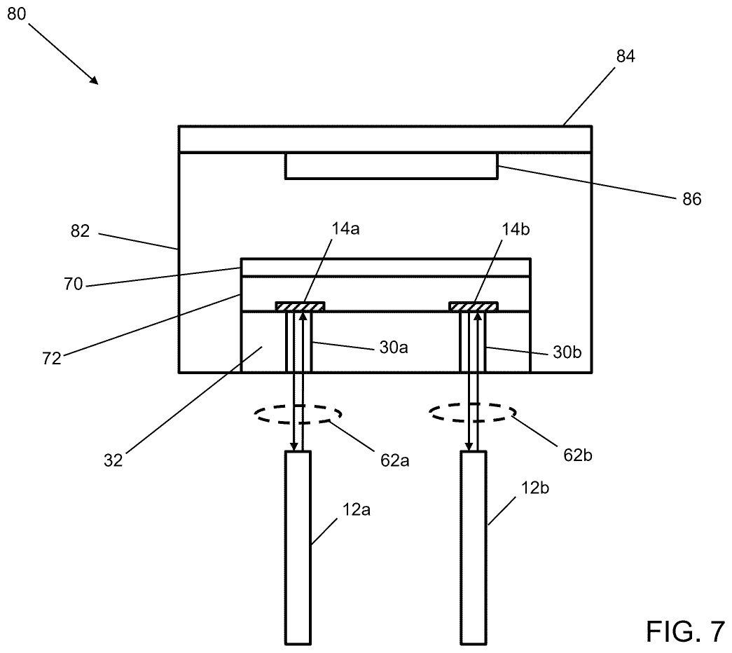

FIG. 7 illustrates another temperature sensing system 80 for a semiconductor processing chamber 82. In this example, an ESC 72 supports a wafer 70 but a pair of sensing elements 14a, 14b are applied or embedded in the underside of the ESC 72. Here a structural element 32 supports the ESC 72 with a pair of passages 30a, 30b aligned with the sensing elements 14a, 14b to enable corresponding optical fibers 12a, 12b to direct source beams 18 at the sensing elements 14a, 14b. If required (as shown in dashed lines) lenses 62a, 62b can also be used to focus the source beams 18. In this example, a showerhead 86 is shown supported beneath a lid 84 of the chamber 82.

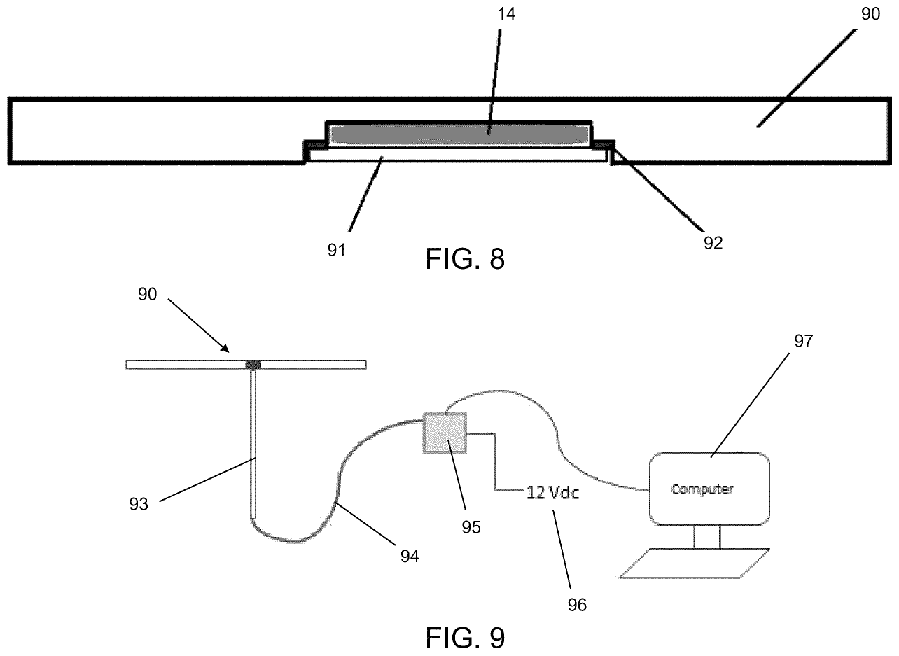

Yet another configuration is shown in FIG. 8 in which a silicon wafer 90 includes a sensing element 14 embedded in its underside, e.g., on a recessed pocket in the silicon water 90 and downwardly facing to interact with the source beam 18 of an optical fiber 12 (not shown). The phosphor sensing element 14 in this example is protected from its environment by a sealing window 91 that is sealed in the recessed pocket using an adhesive 92 or binding joint.

The configuration shown in FIG. 8 enables the temperature of the silicon wafer 90 to be measured using the sensing element 14. An example of a system configuration is shown in FIG. 9, in which a light guide or other light transmission component 93 is positioned adjacent and in alignment with the sensing element 14 on the silicon wafer 90. The component 93 can be a sapphire rod or any other suitable material. The component 93 is coupled to a converter 95 via a cable 94 (e.g., an SMA patch cord). The converter 95 is powered by a power supply 96 (e.g., 12 VDC as illustrated) and can be coupled to a computer 97 or other computing device to enable a temperature sensing operation.

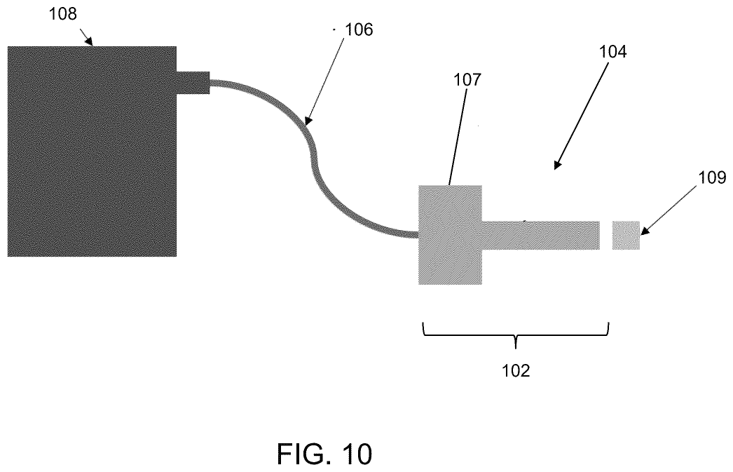

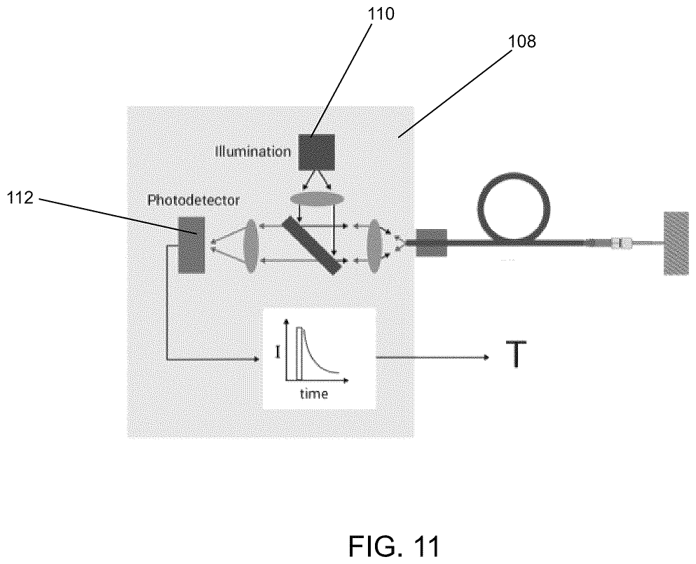

FIGS. 10-16 provide additional detail for the configuration shown in FIG. 5. FIG. 10 shows an optical temperature sensor having a temperature probe 102, comprising a tip 109 and a mount 104. The mount 104 contains a fiber optical cable 106 therein and this fiber optical cable 106 extends out from the mount 104 to optically couple the mount 104 to a temperature sensor converter 108. As illustrated in FIG. 11, the temperature sensor converter 108 contains therein, an illumination device 110 for providing a source beam 18 to be projected down the fiber optical cable 106 and a photodetector 112 to receive a return beam 20.

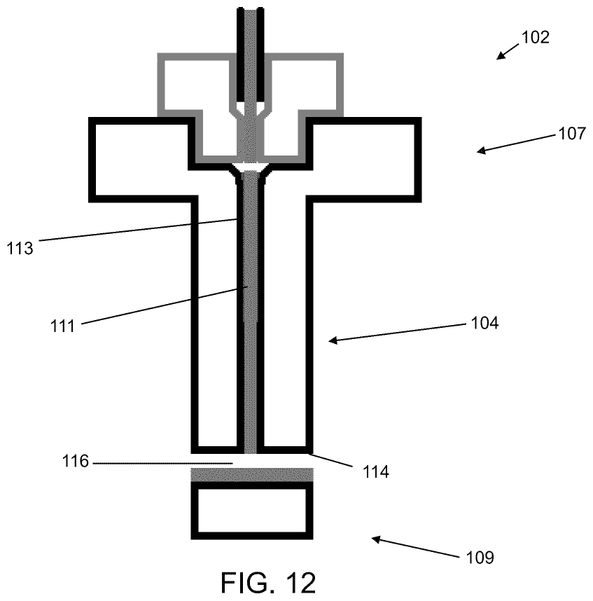

FIG. 12 illustrates a fiber optic temperature sensor 102 having a shaft 104, a tip 109, and a base 107. An optical fiber 111, fed through optical cable 106, run through a channel 113 in the shaft 104 and base 107. Although various types of optical fibers 111 would be known to a person skilled in the art, in an embodiment, the fiber 111 is a fused silica fiber with a silica cladding. While various sizes of fibers would be known, in an embodiment, the fiber has a 1 mm diameter. The optical fiber 111 is exposed at the bottom end 114 of the shaft 104. Below the shaft 104, and spaced from the shaft 104, is the tip 109. Since the tip 109 is spaced from the shaft 104, the space between the shaft 104 and the tip 109 contains the atmosphere of the environment in which the sensor 102 is being used. The space, or gap 116, between the shaft 104 and tip 109 can vary, e.g., approximately, 0.25 to 1.5 mm. By increasing the power of the light source, an increased distance between the optical fiber 111 and the tip 109 can be used.

The optical fiber 111 is held in place by the base 107 and shaft 104, however the illumination device 110, photodetector 112 and means for processing the light and wavelength returning to the temperature sensor converter 108 can be located external to probe 102, as shown in FIG. 11. The optical fiber 111 extends outside the probe 102 as part of optical cable 106. In this way, the light source and means for processing a light signal can be located away from the any harsh environment in which the temperature sensor is being used.

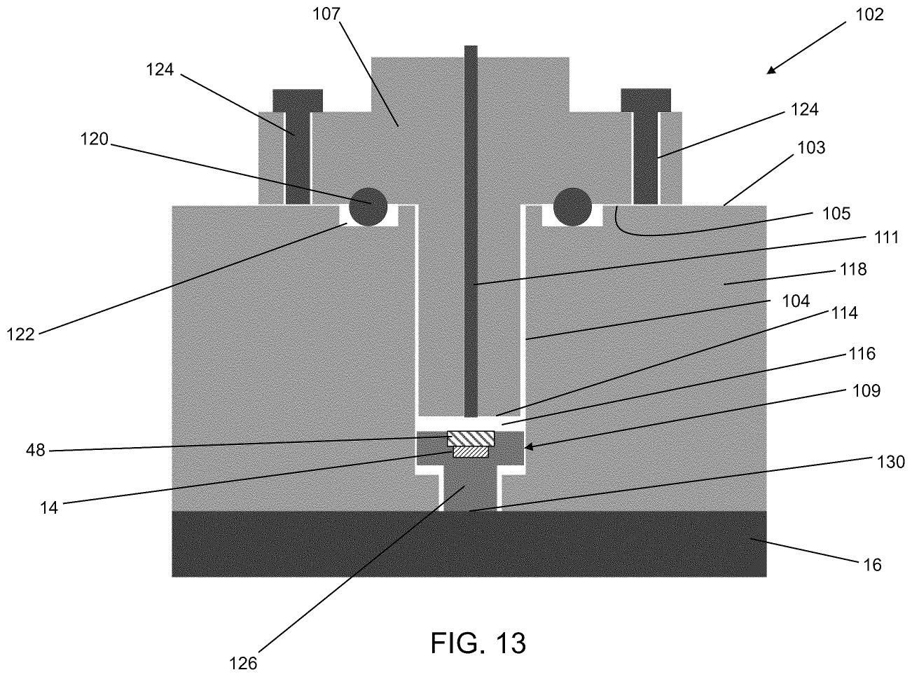

FIG. 13 shows the temperature sensor 102 fixed to the body of a showerhead for use in semiconductor environments. While the temperature sensor 102 described herein could be used in a variety of environments, due to the harsh nature of semiconductor chambers, the temperature sensor 102 has particular advantages for use in semiconductor environments, for example in semiconductor deposition chambers or semiconductor etch chambers. However, it will be appreciated by a person skilled in the art that the temperature sensor 102 could be used in any environment suitable for a contact optical temperature sensor. As such, the design of the base 107 can be varied to be suitable for use in any environment where an optical contact temperature sensor is required.

Referring back to FIG. 13, the temperature sensor 102 is coupled to the body of the showerhead 118. In order to maintain a firm seal with the showerhead 118 a sealing device, such as the O-ring 120 is compressed between the top surface 103 of showerhead 118 and the bottom surface 105 of base 107. As can be appreciated, other methods of sealing would be known to a person skilled in the art. This seal is used to maintain the vacuum in the semiconductor chamber. However, in other applications where a sealed air-tight environment is not required, the seal can be omitted. The O-ring 120 sits in groove 122 of the showerhead 118 to provide proper positioning of the O-ring 120 relative to the sensor base 107 and to allow for ease of assembly without the O-ring 120 shifting. The base 107 may then be fixed to the showerhead 118 using screws 124 in this example. Although screws 124 are shown for coupling the base 107 to the showerhead 118, other fastening mechanisms could be used. While only two screws 124 are shown in the figures as points of attachment, it can be appreciated that any suitable number of points of attachment could be used.

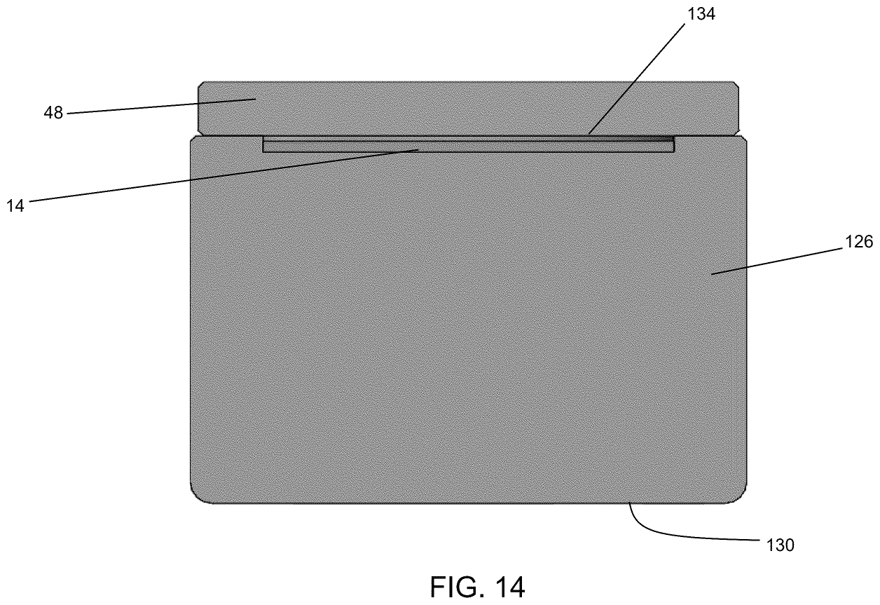

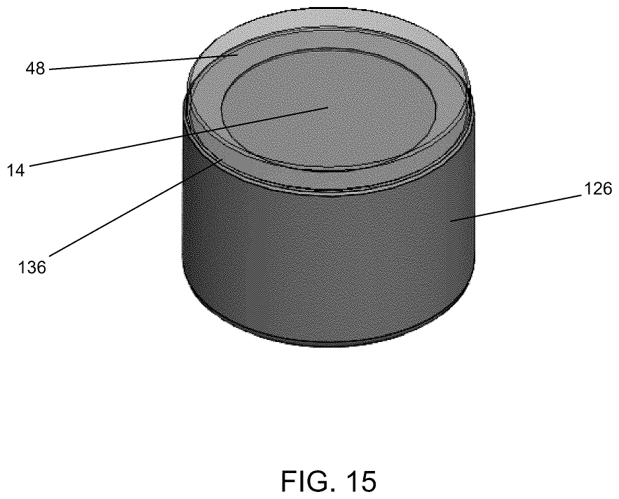

The tip 109, shown in FIGS. 14 and 15, has a body 126 made of a thermally conductive material. In a preferred embodiment, the body 126 is made of alumina. While other suitable materials may be known to a person skilled in the art, alumina allows for good conductivity while being resistant to high temperatures and corrosive environments, such as those in semiconductor deposition chambers containing plasma and other chemicals such as, Fluorine.

Within the tip 109 is a layer of sensing material 14. This sensing material 14 can be phosphorescent such as phosphor, although other materials would be known to a person skilled in the art.

The sensing material 14 is applied onto the thermally conductive tip 109. In order to do this, the sensing material 14 can be mixed with a suitable adhesive.

Application of the sensing material 14 and adhesive combination can be done by any suitable method known to a person skilled in the art including, but not limited to deposition, sputtering, bonding, panting, and spin on. The sensing material 14 is excited by light transmitted through the optical fiber 111. As stated above, the body material 126 is thermally conductive to increase the heat flow from the measurement surface 130 of the measured object 16, to the sensing material 14 for more accurate measurement.

The sensing material 14 can be protected from the environment using a window 48 positioned between the sensing material 14 and the gap 116. The window 48 is sealed to the body 126 of the tip 109 using any suitable sealing process that will hermetically seal the window 48 between the body material 126 and the gap 116. An adhesive having high temperature resistance and resistance to radicals can be used.

The window 48 is transparent to allow for light to be transmitted from the optical fiber 111 to the sensing material 14. Although a variety of materials could be used for the window 48, a suitable example material is sapphire as it is highly transparent, compatible with the preferred hermetic sealing technique (described below), capable of surviving high temperature environments and resistant to the harsh chemical environment of a semiconductor chamber. Furthermore, sapphire and alumina have similar coefficients of thermal expansion and thus a seal can be maintained between the two even as the temperature changes. In this respect, similar coefficients of thermal expansion can be defined as coefficients of thermal expansion which are sufficiently similar such that when window material and body material expand and contract, the rates and amount of expansion and contraction are not so different as to cause separation between the two. Typically, materials wherein the difference in coefficients of thermal expansion is in the range of 6-10×10⁻⁶° C. or less will be suitable. It can be appreciated by a person skilled in the art that other window and tip materials with similar coefficients of thermal expansion could be used.

As can be seen in FIG. 13, the body 126 of the tip 109 has a shoulder or sealing surface 136 to allow for the sealing of the window 48 to the body 126 without contacting the sensing material 14. The outer edges of the window 48 can be affixed to the body 126 using zinc borosilicate glass due to its ability to adhere to both sapphire and alumina and maintain adhesion in high temperature applications. Although zinc borosilicate glass is used as an adhesive in a preferred embodiment, other adhesives would be known to a person skilled in the art.

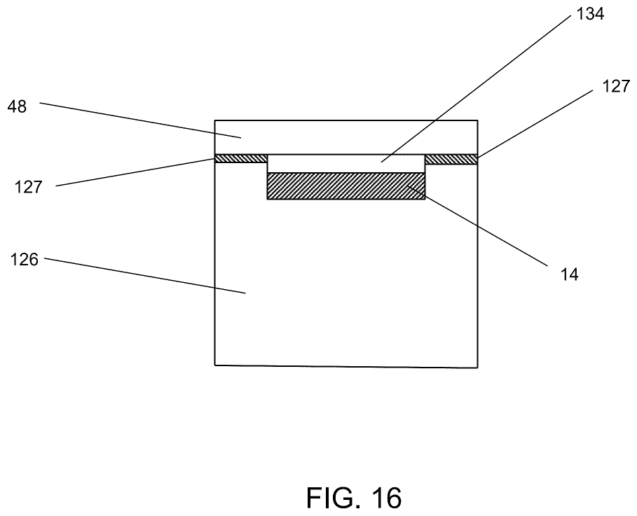

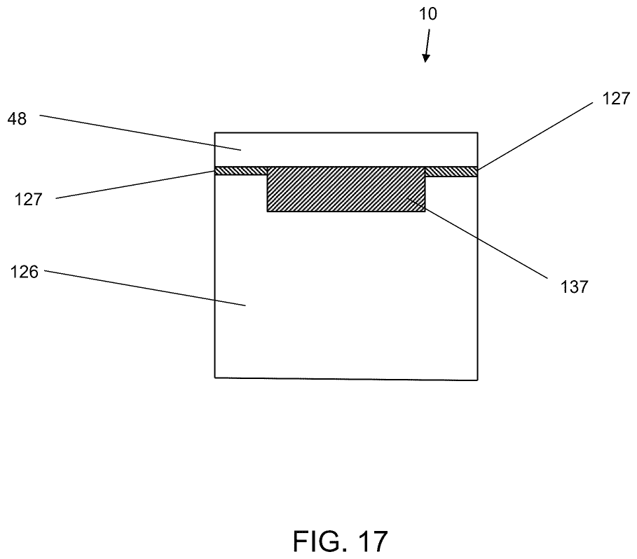

In order to create the hermetic seal, the adhesive, for example zinc borosilicate glass, is heated. For zinc borosilicate glass, it is heated to approximately 400° C. to 700° C. A film of the adhesive can be applied to the sapphire, or alumina, or both the sapphire and alumina, using any suitable method, including, but not limited to, chemical vapor deposition, sputtering, evaporating and spin on. FIG. 16 shows the sealing material 127 between the window 48 and the body 126.

In an embodiment, the application of the glass seal can be screen printed or painted onto the surface. A stencil is made with a geometry adapted to fill the volume of space between the sensing material and the sealing surface. The glass seal is applied, and the stencil is removed. The window is then placed atop the adhesive using a fixture to ensure concentricity between the window to the tip. The entire assembly is then placed in a furnace and baked at atmospheric pressure.

A layer of gas 134, such as air, can be left between the sensing material 14 and the window 48. This layer of gas 134 ensures that the sensing material 14 does not touch the window 48. In this way, the sensing material 14 is inhibited from losing heat to the window 48 which aids in more accurate temperature measurements.

The window 48 can be directly sealed onto the probe tip 109 in which the sensing material 14 is applied. By sealing the window 48 in the probe tip 109, the tip assembly is self contained and can be used for various tip geometries to maximize contact and heat transfer from the measured surface 130.

In an alternative embodiment a transparent coating of sapphire or other suitable material, such as aluminum oxide, is applied on to the upper surface of the body of the tip 126 to completely cover the sensing material 14, isolating the sensing material 14 from the surrounding environment. This could be done with a variety of different methods such as, but not limited to, deposition, screen printing or with a thermal spray coating process.

When in use, the tip 109 can be placed in contact with the measured object 16 for which the temperature reading is required. Since the body 126 of the tip 109 is made of conductive material, the heat flows from the measurement surface 130 through the body 126 of the tip 109 and to the sensing material 14. A source beam 18 from the illumination device (shown in FIG. 11) is provided using the optical fiber 111. The light shines through the transparent window 48 and on to the sensing material 14. The incoming light of the source beam 18 excites the sensing material 14 causing it to emit a wavelength of light (i.e. the return beam 20) back through the window 48 and into the optical fiber 111. This light is transmitted through the optical cable 106 to the temperature sensor converter 108. Since the wavelength emitted by the sensing material 14 is correlated to the temperature of the sensing material 14, the temperature sensor converter 108 uses the wavelength to determine the temperature of the sensing material 14 which is reflective of the temperature of the measurement surface 130. In the embodiment having a tip body material of alumina and a window material of sapphire, temperature can be measured with an accuracy of approximately +/−2° C.

By separating the tip 109 from the shaft 104, heat loss from the tip 109 to the shaft 104 is reduced compared to traditional optical temperature sensors. This improves the accuracy of the measurement by reducing the difference in the temperature of the sensing material 14 and the measurement surface 130. Furthermore, since the optical fiber 111 is spaced from the tip 109, heat transfer from the tip 109 to the optical fiber 111 is reduced. This allows materials which have a lower temperature tolerance to be used to make the optical fiber 111, reducing cost. Furthermore, the number of parts required for assembly can also be reduced. By isolating the sensing material 14 from the surrounding harsh environment, durability of the probe can be increased, and should the tip eventually degrade, it would be possible to replace just the tip 109 as opposed to the entire probe 102.

FIG. 17 shows an example embodiment of sensing material within the tip 109 being isolated from the surrounding environment. The sensing material, e.g., sensing material 14, can be encapsulated in a transparent, non porous coating of glass or other suitable encapsulating material. In FIG. 17, the sensing material and the encapsulating material are identified by the reference numeral 137, and hereinafter jointly referred to by as the encapsulated sensing material 137.

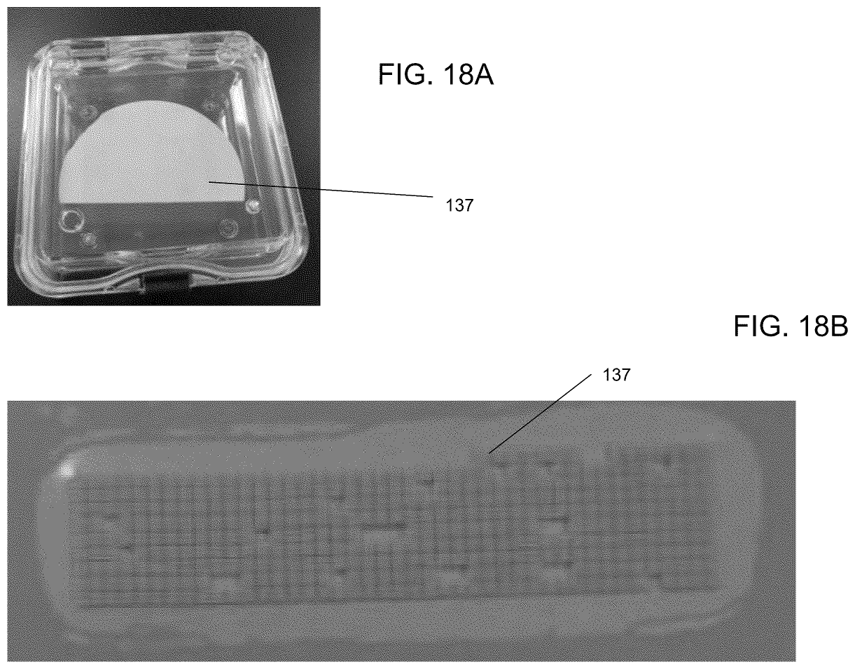

It is understood that the encapsulated sensing material 137 can be a variety of different shapes and sizes, depending on the required application. For example, FIG. 18A shows the encapsulated sensing material 137 as a wafer. The shape or size of the encapsulated sensing material 137 can be further configured or manipulated at various stages of assembly or manufacture. For example, FIG. 18B shows the encapsulated sensing material 137 in a diced wafer shape. The shape can be the result of machining or manipulating the wafer encapsulated sensing material 137.

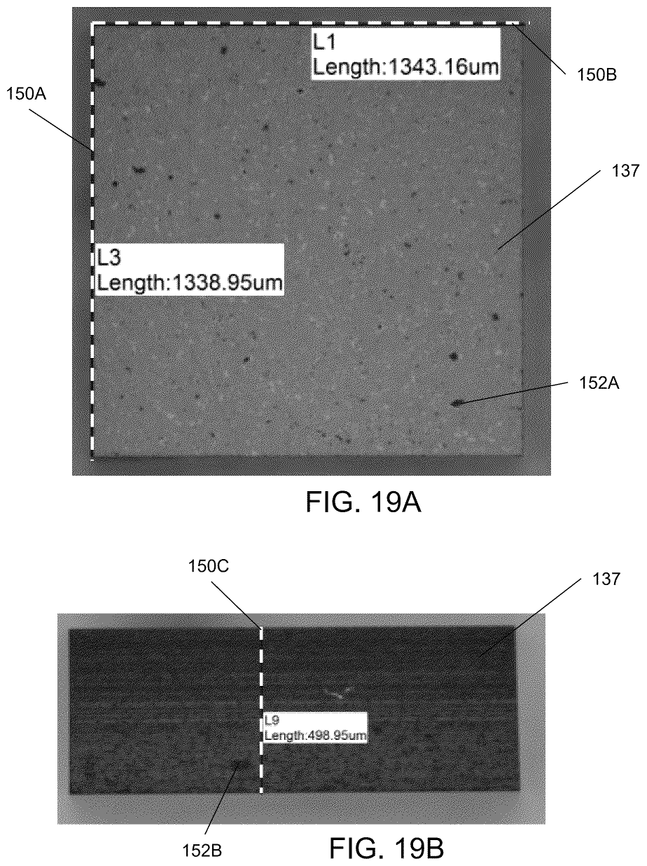

FIGS. 19A, 19B each show magnified images of the structure of an example Thermographic Phosphor in Glass (TPiG) encapsulated sensing material 137. In the top view shown in FIG. 19A (with the field of view of the image defined by a height 150A (1338.95 micrometers) and a length 150B (1343.16 micrometers) of the sample), the potential high hermiticity of the example encapsulated sensing material 137 is shown owing to relatively few black spaces 152A indicative of low hermicity. The cross-sectional view shown in FIG. 19B (with the shown sample having a depth 150C of 498.95 micrometers) similarly shows the potential high hermiticity owing to the relatively few dead spaces 152B in the image.

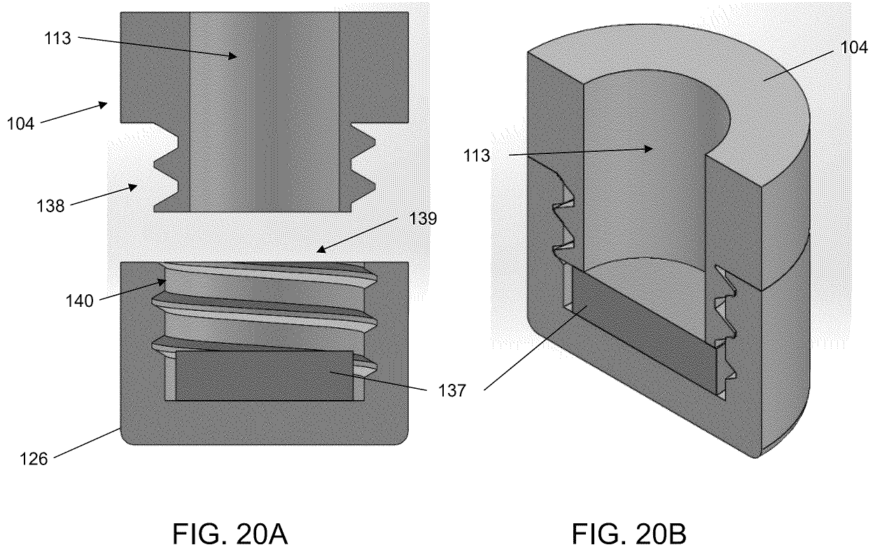

By encapsulating the sensing material 14 into the encapsulated sensing material 137, the sensor 10 may not only isolate the sensing material 14 from the surrounding environment, but may possibly protect the sensing material from physical wear or impact, or allow for rougher or less sensitive handling or assembly. For example, in the embodiment shown in FIGS. 20A, 20B, the encapsulated sensing material 137 can be used in part to define an assembly. In FIGS. 20A, 20B, the channel 113 extending through the shaft 104 is shown having a threaded end 138. The body 126 of the tip 109 includes a channel 139 which is sized to receive the threaded end 138, and further includes threading 140 to enable mating with the threaded end 138. In FIG. 20B, the threaded end 138 is shown mated with the threading 140 and threaded to contact the encapsulating sensing material 137. Assembly of the temperature probe 10 is therefore easier as the encapsulating sensing material 137 provides feedback as to when the shaft 104 is completely engaged with the tip 109.

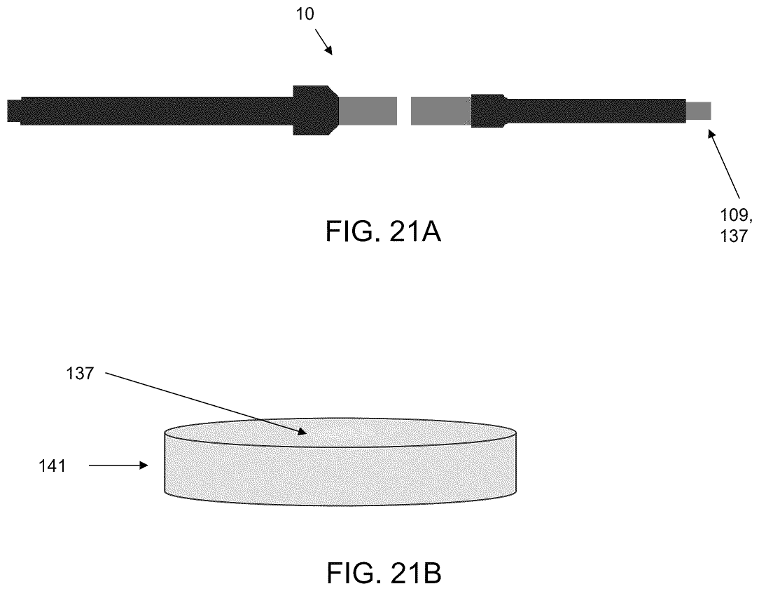

In example embodiments, the encapsulated sensing material 137 can be assembled in a manner similar to that discussed herein with respect to the isolated sensing material 14. For example, the encapsulated sensing material 137 can be secured via adhesive to the tip 109. In example embodiments, the tip 109 can consist of the encapsulated sensing material 137 (FIG. 21A). The encapsulated sensing material 137 can be applied to a measured object 141 (FIG. 21B), in a recess of that object 141, etc. The encapsulated material 137 can be used in the angled applications discussed in respect of FIG. 2.

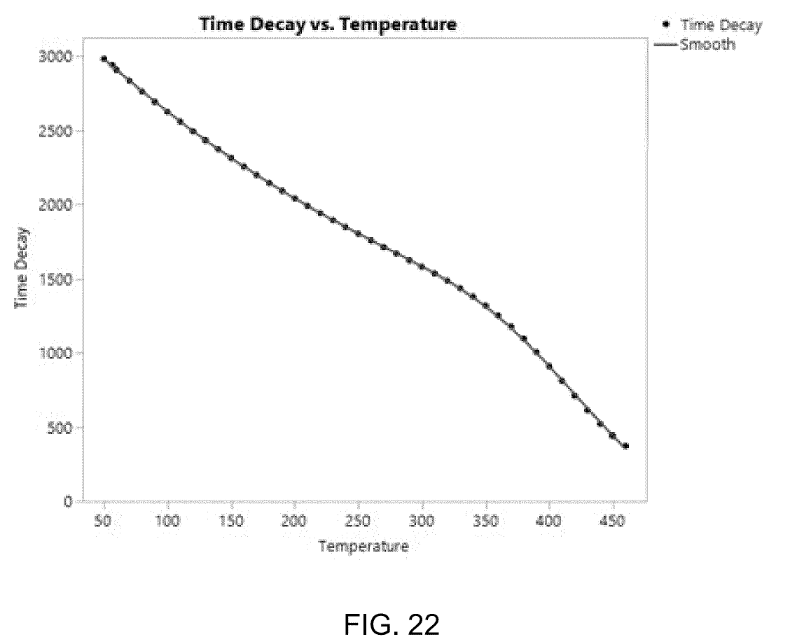

FIG. 22 shows experimental results of testing an example TPiG encapsulated sensing material 137 at different temperatures. In the shown chart, the time constant of the measured TPiG encapsulated sensing material 137 is shown on the vertical axis, and the temperature being measured is shown on the horizontal axis. Importantly, and as discovered, the relationship between the TPiG encapsulated sensing material's time constant and the temperature being measured is monotonic (in this shown graph continuously sloping downward) even at high temperatures, so that a single measurement of the time constant can be correlated to a measured temperature. Moreover, as shown by the slope of the graph, the performance of the example TPiG encapsulated sensing material 137 is relatively consistent, possibly allowing for easier calibration.

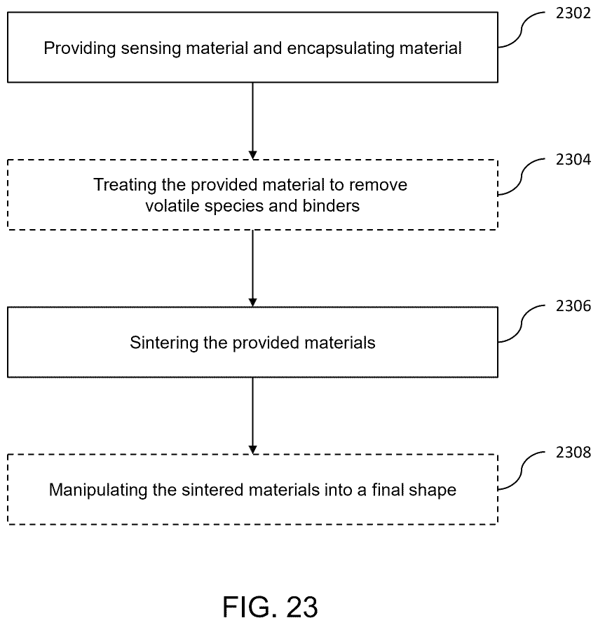

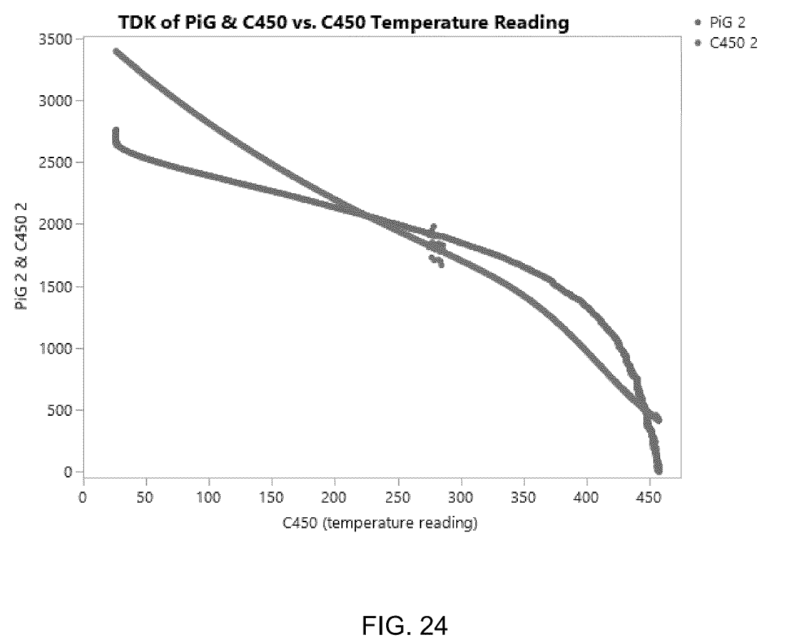

An example method of creating the encapsulated sensing material 137 is shown in FIG. 23. Generally, the sensing material 14 can be encapsulated into the encapsulated sensing material 137 via sintering.

At block 2302, the sensing material 14 and the material used to encapsulate the sensing material 14 to form the encapsulating sensing material 137 are provided. In at least some example embodiments, the sensing material 14 is a thermographic phosphor, and the encapsulating material includes glass, binders, and/or other types of additive materials. The materials can be in a powder, crystal or other non-liquid form, or the materials can include at least some liquid materials.

Providing the materials sensing material 14 and the encapsulating material can, in at least some example embodiments, include molding or manipulating the mixed materials into a final shape or precursor shape. For example, the mixed materials may be provided in a mold in the shape of a wafer or ingot. The molding can require an initial compaction or heating to ensure the mixed materials take the shape of the mold.

Optionally, at block 2304, the sensing material 14 and the encapsulating material can be treated to remove volatile species and binders (whether organic or inorganic). Treating can comprise heat treatment, or other types of treatment. The block 2204 may be unnecessary where the sensing material 14 or the encapsulating material do not include volatile species or binders which cannot be removed via heat treating.

At block 2306, the mixed materials are sintered in a controlled atmosphere to create an optically transparent, non-porous material. The controlled atmosphere can be a vacuum, or controlled to substantially be composed of or include a sufficient amount of inert gases to avoid adverse reactions. In example embodiments, the controlled environment is primarily composed of air. Sintering can result in a non-porous, structured material that will block the diffusion of gasses into the encapsulating sensing material 137 which would otherwise affect the light scattering properties of the encapsulating sensing material 137. Encapsulated sensing material 137 created at least in part by sintering can exhibit high hermiticity, increasing the material's durability in harsh environments.

Optionally, at block 2308, the encapsulating sensing material 137 can be manipulated into a final shape. Manipulating can include, for example, dicing, laser cutting, machining, or other suitable methods known to a person skilled in the art.

Advantageously, the disclosed TPiG encapsulated sensing material 137 may have lower sample to sample variability, allowing for more consistent and reliable temperature probes. The greater sample to sample variability can result from the sintering process, where the thermographic phosphor sensing material 14 does not change its chemical composition during sintering, allowing for greater control of the final composition of the TPiG encapsulated sensing material 137. As a result, sintering can allow for more precise selection of the sensing material 14, to target specific operating environments (e.g., high temperature environments). Moreover, the TPiG encapsulated sensing material 137, owing to its generation via sintering or a similar process, can allow for greater uniformity between TPiG encapsulated sensing material 137 batches as the TPiG encapsulated sensing material 137 results in a more predictable shape and composition compared to other approaches (e.g., a ceramic blend approach). For example, with sintering, different TPiG encapsulated sensing materials 13 may have similar amounts of thermographic phosphor (i.e., sensing material) through the control of the amount of thermographic phosphor input, whereas in a ceramic blend approach, the amount of sensing material may vary as the sensing material amounts may be eroded or created as a result of less predictable or more variable chemical interactions. In another example, with sintering, the final shape of different TPiG encapsulated sensing materials 13 may be more consistent, as sintering may cause the TPiG encapsulated sensing materials 13 to shrink with a greater degree of predictably into a final shape (e.g., the expected shrinking can be accounted for by way of mold creation and material selection).

Additionally, the described sintering process can advantageously allow for selection of encapsulating material that can reduce porosity of the TPiG encapsulated sensing material 137 to a relatively larger extent given the aforementioned stability of the TPiG, increasing the overall robustness of the TPiG encapsulated sensing material 137. For example, materials which have reduced porosity may be selected without regard to the encapsulating material's properties that define chemical interactions with the sensing material. Moreover, given the aforementioned stability of the TPiG, the encapsulating material can be selected to facilitate specific applications, such as a high temperature application. For example, the encapsulating material can be a glass which performs well in high temperature environments. More particularly, in example embodiments, the TPiG encapsulated sensing material 137 can be a sensor with a glass encapsulating material that performs well in environments having a temperature of 450 degrees Celsius, or as high as 750 degrees Celsius, or even as high as 900 degrees Celsius.

While FIGS. 6 and 7 show examples of temperature measurement of a wafer during processing or of the wafer support or electrostatic chuck which supports the wafer under process, it is often desirable to measure and control the temperature of other regions or components in the process chamber to achieve uniform results and high yield. In various embodiments examples of such components the temperature measurement system may include a portion of an edge ring or shower head or chamber wall. In various embodiments sensing the temperature of chamber or structural components in the process chamber may be different than sensing the temperature of a wafer. The wafer is introduced into the chamber to be processed and is then removed. Chamber components stay in the chamber for many process and cleaning cycles and thus may have different requirements than a wafer sensor.

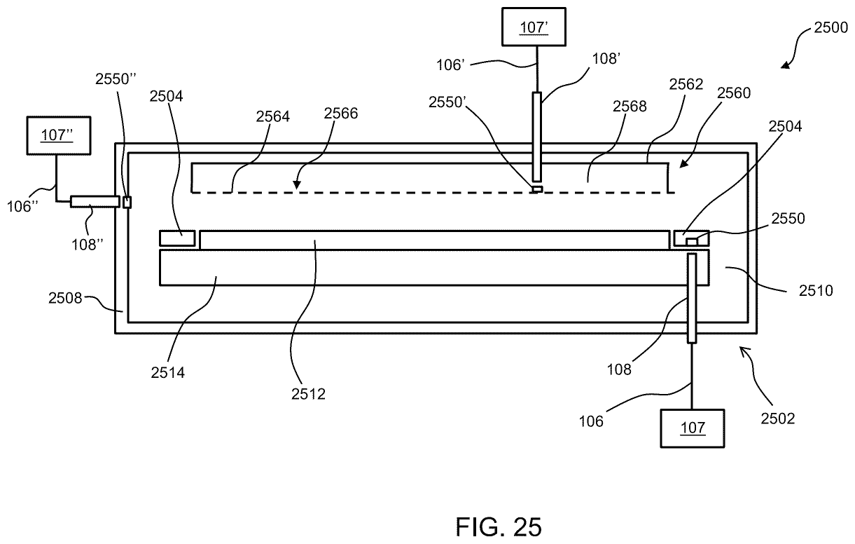

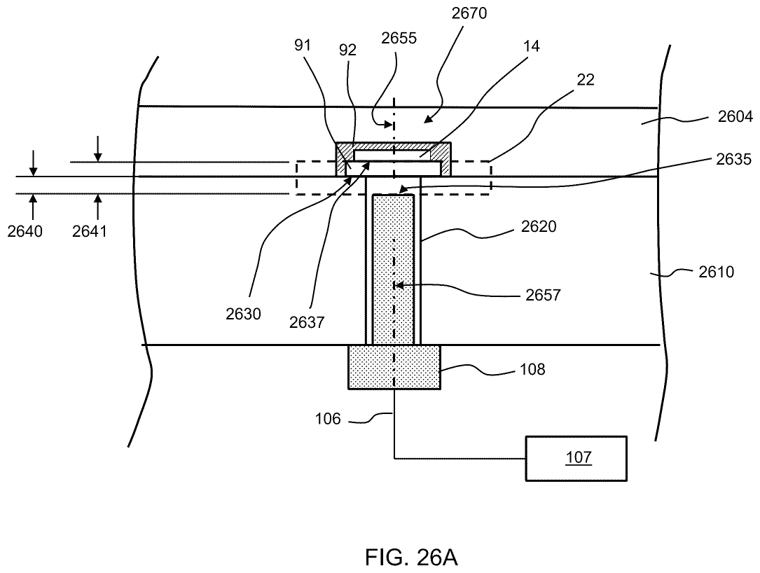

FIG. 25 shows an example embodiment of a semiconductor process tool 2500 including chamber 2502 that has an interior volume 2510 surrounded by chamber wall 2508. In various embodiments, the chamber 2502 includes various structural elements or chamber components including, for example, a wafer support or electrostatic chuck 2514, an edge ring 2504, a shower head 2560 having a shower head enclosure 2562, a gas diffuser 2564 having gas outlets 2566, and an interior volume 2568. Also shown in FIG. 25 is wafer 2512 (the wafer to be processed) supported by the electro-static chuck 2514.

FIG. 25 shows three example embodiments of temperature measurement configurations, a first configuration to measure the temperature of a portion of the edge ring 2504, a second configuration to measure the temperature of a portion of the shower head 2560 and a third configuration to measure the temperature of a portion of the chamber wall 2508.

The configuration to measure the temperature of a portion of edge ring 2504 includes a converter 107, a probe 108 having a first end and a second end, where the first end is different from the second end, where the second end is optically coupled to converter 107 by an optical pathway or optical fiber 106, and a sensing element 2550 which is optically coupled to the first end of probe 108.

The configuration to measure the temperature of a portion of shower head 2560 includes the converter 107′, the probe 108′ having a first end and a second end, where the first end is different from the second end, where the second end is optically coupled to converter 107′ by optical pathway or optical fiber 106′, and a sensing element 2550′ which is optically coupled to the first end of the probe 108′.

The configuration to measure the temperature of a portion of chamber wall 2508 includes a converter 107″, a probe 108″ having a first end and a second end, where the first end is different from the second end, where the second end is optically coupled to the converter 107″ by optical pathway or optical fiber 106″, and a sensing element 2550″ which is optically coupled to the first end of the probe 108″.

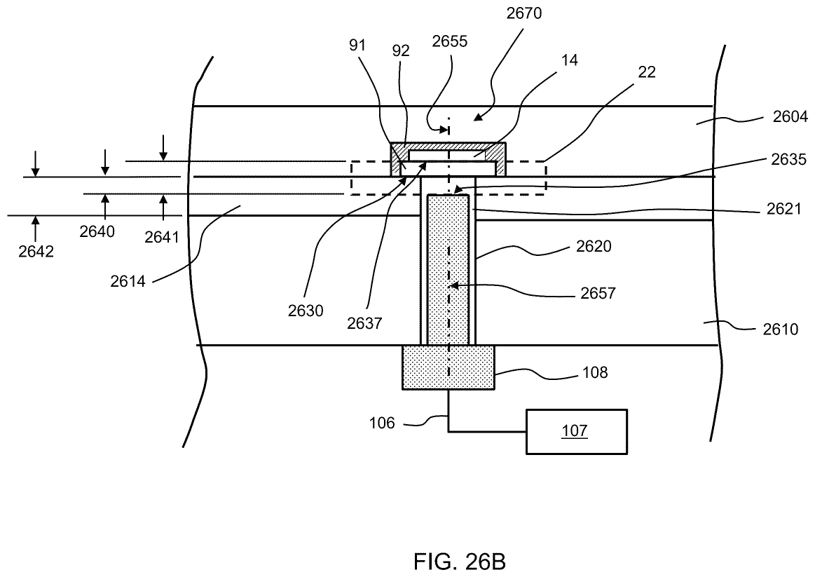

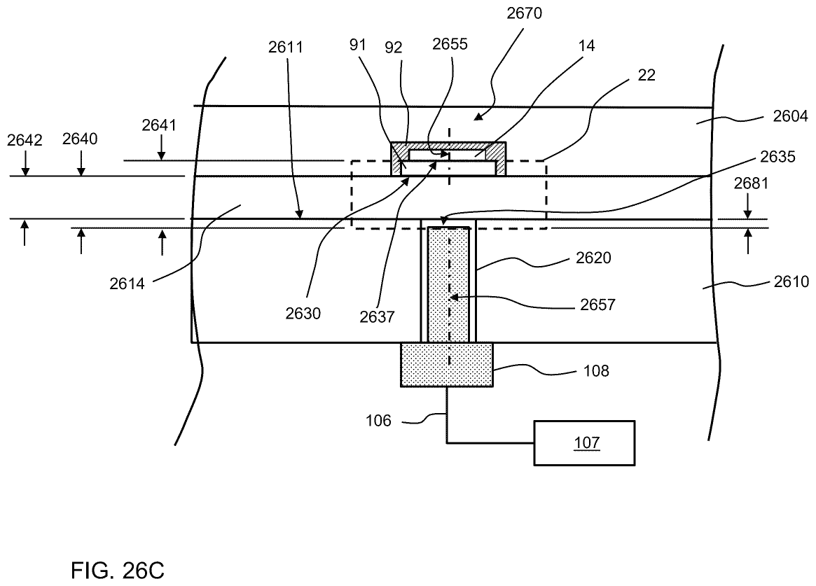

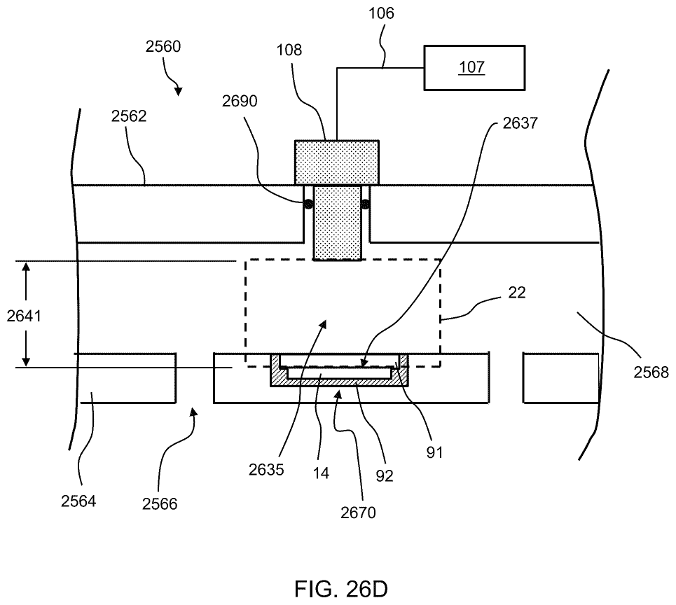

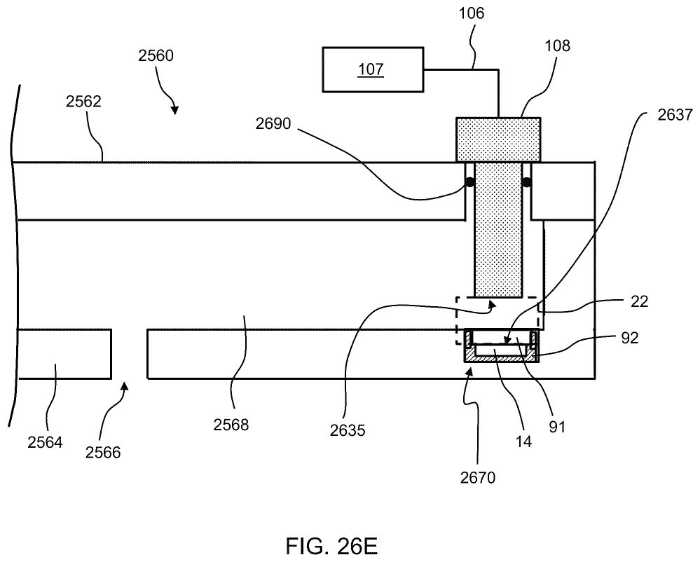

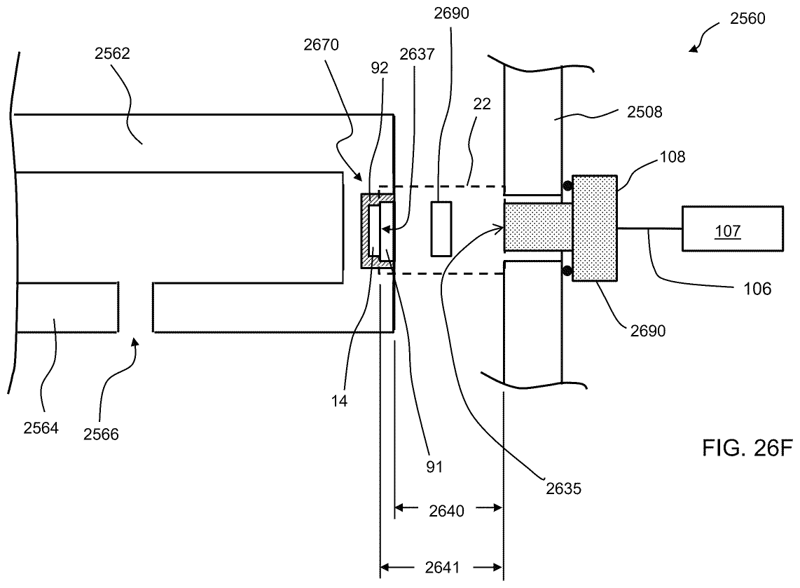

FIG. 26A shows an example embodiment of a system configured to measure the temperature of a portion of a structural element 2604 that is in thermal communication with a sensing element 14. The cross-sectional schematic shown in FIG. 26A includes a portion of a structural element 2604, a portion of an optional first base 2610 configured to at least partially support the structural element 2604 and having a channel 2620 formed in a portion of the first base 2610 into which at least a portion of the a probe 108 is inserted, where the probe 108 has a proximal and distal end, the distal end optically coupled to a converter 107 by an optical pathway 106, and a remote sensor component 2670 disposed in or on or partially in a portion of the structural element 2604, where the remote sensor component 2670 includes the sensing element 14 and an optional window 91, and where the sensing element 14 is in thermal communication with at least a portion of the structural element 2604 and the proximal end of the probe 108 is optically coupled to the sensing element 14. The remote sensor 2670 is spaced apart from the proximal end of the probe 108 by a gap 2640. This gap 2640 significantly reduces or eliminates the thermal communication between the probe 108 and the remote sensor 2670, resulting in a more accurate temperature measurement. In various embodiments, the gap 2640 may be in the range of about 0 mm to about 200 mm, or in the range of about 1 mm to about 100 mm, or less than about 50 mm, or less than about 25 mm, or less than about 10 mm, or less than about 5 mm, or less than about 1 mm.

In various embodiments, the window 91 may be configured or selected to protect the sensing element 14 from corrosive elements (for example gases, liquids, particles, etc.) in the process chamber. In various embodiments, window 91 may be configured or selected to eliminate contamination of the process environment by sensing element 14. In various embodiments, protection and/or contamination prevention may be achieved by coating the portions of the sensing element 14 that are exposed to the process environment. In various embodiments, a coating may include on or more layers of silica, quartz, sapphire, alumina, diamond, silicon carbide, silicon nitride, silicon of the like.

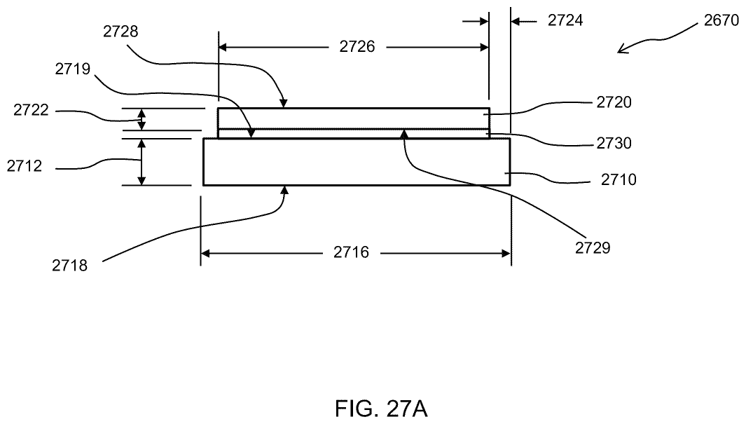

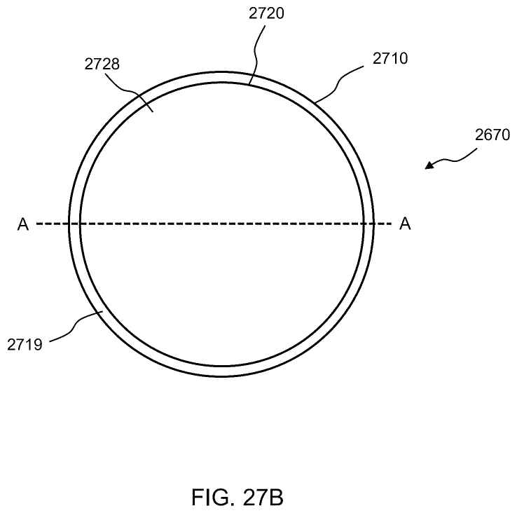

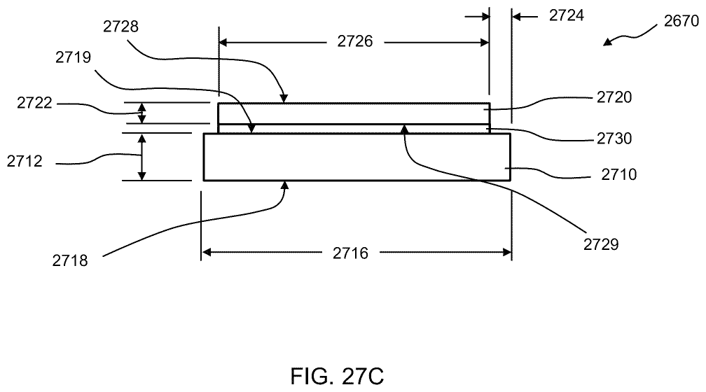

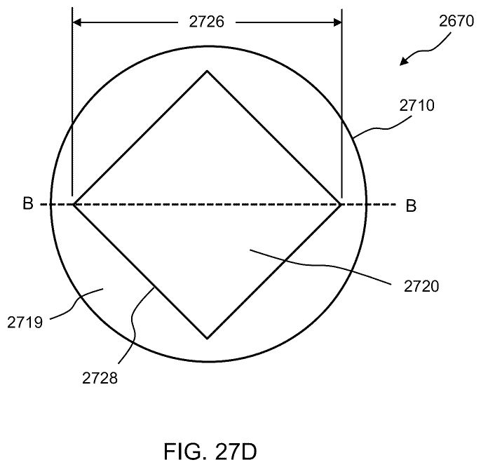

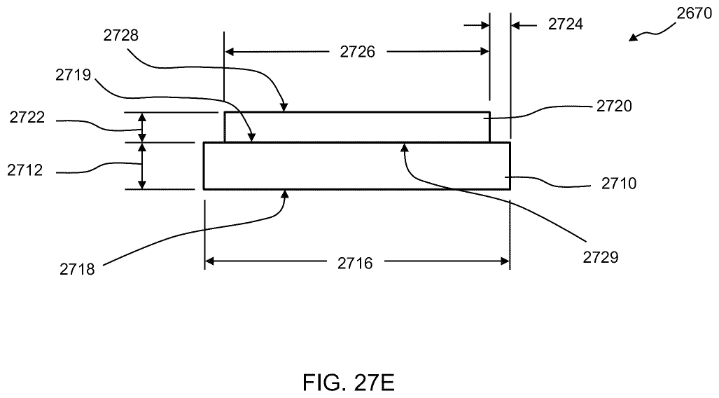

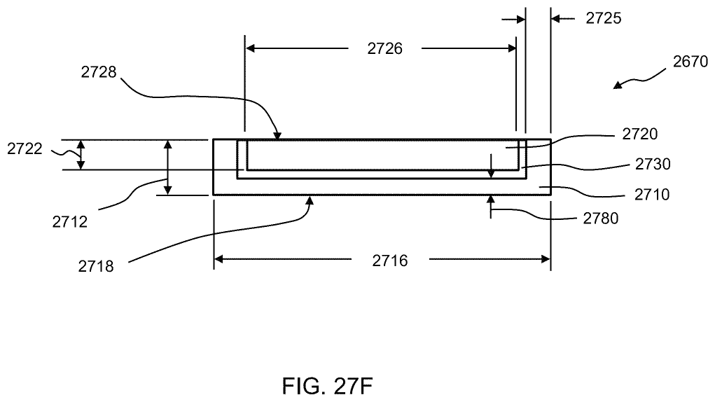

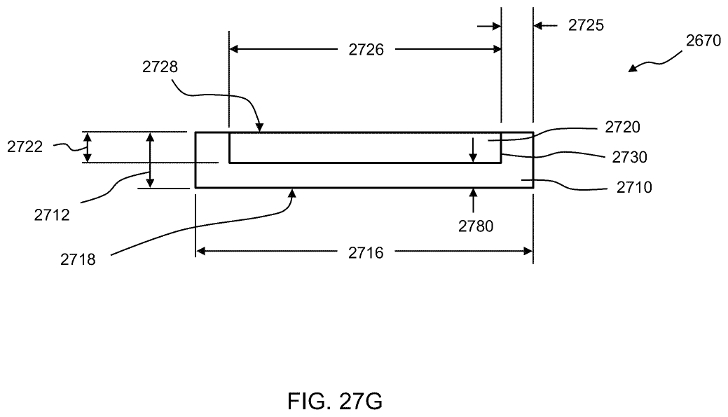

In various embodiments, the remote sensor component 2670 has a sensor optical axis 2655 and the probe 108 has a probe optical axis 2657. In various embodiments, the sensor optical axis 2655 and the probe optical axis 2657 are aligned or co-linear. In other embodiments, the sensor optical axis 2655 and the probe optical axis 2657 may not be co-linear. In various embodiments, the sensor optical axis 2655 and the probe optical axis 2657 may be mis-aligned. In various embodiments a displacement perpendicular to the sensor optical axis 2655 and the probe optical axis 2657 between the sensor optical axis 2655 and the probe optical axis 2657 may be less than 3 mm, or less than 1 mm. or less than 500 microns or less than 250 microns, or less than 100 microns. In various embodiments, a displacement perpendicular to the sensor optical axis 2655 and the probe optical axis 2657 between the sensor optical axis 2655 and the probe optical axis 2657 may be less than half the extent of the size of the sensing element 14, for example, less than half of diameter 2726 in FIG. 27A or less than half the diameter 2726 in FIG. 27B.

Referring to FIG. 26A, in various embodiments, the boundary 22 is disposed between the proximal end 2635 of the probe 108 and the front face 2637 of the sensing element 14. In other embodiments, the boundary 22 may not include the entire region between the proximal end 2635 of the probe 108 and the front face 2637 of the sensing element 14.

Referring to FIG. 26A, the boundary 22 is shown in dashed lines to illustrate that the boundary 22 can take the form of a physical boundary such as an optically transparent (or partially transparent or translucent) “window” or passage (for example an optional window 91), and/or may represent a gap between the proximal end 2635 of the probe 108 and the front face 2637 of the sensing element 14 and/or any structural element(s) (not shown in FIG. 26A for clarity) that contain or support them. In various embodiments, boundary 22 includes an optional window 91 and the free space optical pathway between the proximal end 2635 of the probe 108 and the front face 2630 of the window 91. In various embodiments without optional window 91, the boundary 22 includes the free space optical pathway between the proximal end 2635 of the probe 108 and front face 2637 of the sensing element 14. In various embodiments, the free space may be air, vacuum, or the process gas environment. In various embodiments, boundary 22 may include one or more optical elements, for example a refractive lens, a reflective lens, a mirror, a dichroic mirror, a ball lens, a filter, a dichroic filter or the like. In various embodiments, the boundary 22 may include a gas, a liquid, or a solid or any combination thereof.

In various embodiments, at least the portion of the optional window 91 disposed between the distal end 2635 of the probe 108 and the front surface 2637 of the sensing element 14, or one or more coatings disposed on the sensing element 14 may have a transmission value of at least 25%, or at least 50%, or at least 75% to a wavelength of light utilized in the optical temperature measurement system (e.g., in the range of about 350 microns to about 1,100 microns or in the range of about 390 microns to about 800 microns).

Referring to FIG. 26A, in various embodiments the extent of boundary 22, for example between the front face 2635 of probe 108 and front face 2637 of the sensing element 14, is identified as 2641. In various embodiments the extent 2641 of boundary 22 may be in the range of about zero to about 200 mm, or in the range of about 1 mm to about 100 mm, or less than about 50 mm, or less than about 25 mm, or less than about 10 mm, or less than about 5 mm, or less than about 1 mm. While FIG. 26A shows the extent of boundary 22 between front face 2637 of sensing element 22 and front face 2635 of probe 108 this is not a limitation and in other embodiments the extent of boundary 22 may be different.

In various embodiments the return beam from the sensing element 14 includes at least one characteristic that can be used to determine the temperature of the sensing element. In various embodiments the source beam may be pulsed or modulated such that during a portion of time the source beam is off, and the return beam characterized during at least a portion of the time that the source beam is off. In various embodiments the sensing element may be a phosphor or a thermographic phosphor that emits light in response to the source beam, where the emitted light or phosphorescence has an exponential decay after the source beam is turned off, and the decay rate or decay time constant is proportional to the temperature of the sensing element. In various embodiments, a characteristic of the return beam may include an intensity or amplitude, a change in intensity or amplitude over a time period, an intensity decay rate, an intensity decay rate of an exponential decay, a time constant of an exponential decay, an optical power spectrum, or one or more portions of an optical power spectrum.

FIG. 26B shows an example cross-sectional schematic variation of the system discussed with reference to FIG. 26A, in which an optional second base 2614 is disposed between a structural element 2604 and an optional first base 2610. In various embodiments, the measurement system is configured to measure the temperature of a portion of the structural element 2604 that is in thermal communication with the sensing element 14. The cross-sectional schematic shown in FIG. 26B includes a portion of structural element 2604, a portion of the optional second base 2614 configured to support at least a portion of the structural element 2604 and having a channel 2621 into which at least a portion of the probe 108 is inserted, wherein the optional first base 2610 is configured to at least partially support the optional second base 2614 and having a channel 2620 into which at least a portion of the probe 108 is inserted, wherein the probe 108 has a proximal and distal end, the distal end optically coupled to converter 107 by optical pathway 106, and a remote sensor component 2670 disposed in or on or partially in a portion of structural element 2604, where remote sensor component 2670 includes the sensing element 14 and optional window 91, and where the sensing element 14 is in thermal communication with at least a portion of structural element 2504 and the proximal end of probe 108 is optically coupled to the sensing element 14.

In various embodiments, a boundary 22 is disposed between the proximal end 2635 of the probe 108 and the front face 2637 of the sensing element 14. The boundary 22 is shown in dashed lines to illustrate that boundary 22 can take the form of a physical boundary such as an optically transparent “window” or passage (for example optional window 91), and/or may represent a gap between the proximal end 2635 of probe 108 and the front face 2637 of the sensing element 14 and/or any structural element(s) (not shown in FIG. 26A for clarity) that contain or support them. In various embodiments boundary 22 includes optional window 91 and the free space optical pathway between the proximal end 2635 of probe 108 and front face 2630 of window 91. In various embodiments without optional window 91, boundary 22 includes the free space optical pathway between the proximal end 2635 of probe 108 and front face 2637 of the sensing element 14. In various embodiments the free space may be air, vacuum, the process gas environment; the constituents of the free space environment are not a limitation of the present invention. In various embodiments boundary 22 may include one or more optical elements, for example a refractive lens, a reflective lens, a mirror, a dichroic mirror, a ball lens, a filter, a dichroic filter or the like. In various embodiments boundary 22 may include a gas, a liquid, or a solid or any combination thereof.

In various embodiments optional second base 2614 may have a thickness 2642 in the range of about 50 microns to about 10 mm, or in the range of about 200 microns to about 5 mm, or in the range of about 500 microns to about 3 mm, however the thickness of second base 2614 is not a limitation of the invention.

FIG. 26C shows a variation of the system discussed with reference to FIG. 26B, in which an optional second base 2614 is disposed between structural element 2604 and optional first base 2610. In various embodiments the system is configured to measure the temperature of a portion of a structural element 2604 that is in thermal communication with the sensing element 14. While optional second base 2614 of the system discussed in reference to FIG. 26B has a channel 2621 into which at least a portion of probe 108 may be inserted, in the system of FIG. 26C, optional second base 2614 does not have a channel and boundary 22 and the optical pathway between the sensing element 14 and the proximal end of probe 108 includes at least a portion of optional second base 2614. While FIG. 26C shows the proximal end of probe 108 recessed in channel 2620 by an amount identified as 2681, this is not a limitation and in other embodiments gap 2681 may be zero or substantially zero or the front face 2635 of probe 108 may be proud of the top surface 2611 of first base 2610 (inserted into a recess in second base 2614, not shown in FIG. 26C). In various embodiments, the gap 2681 may be less than about 50 mm, or less than about 25 mm, or less than about 10 mm, or less than about 5 mm, or less than about 1 mm.

Referring to FIG. 26C, in various embodiments boundary 22 is disposed between the proximal end 2635 of probe 108 and the front face 2637 of the sensing element 14. Boundary 22 is shown in dashed lines to illustrate that boundary 22 can take the form of a physical boundary such as an optically transparent “window” or passage (for example optional window 91), and/or may represent a gap between the proximal end 2635 of probe 108 and the front face 2637 of the sensing element 14 and/or any structural element(s) that contain or support them. In various embodiments boundary 22 includes optional window 91, at least a portion of optional second base 2614 and the free space optical pathway between the proximal end 2635 of probe 108 and bottom face 2638 of optional second base 2614. In various embodiments without optional window 91, boundary 22 includes at least a portion of optional second base 2614 and the free space optical pathway between the proximal end 2635 of probe 108 and bottom face 2638 of optional second base 2614. In various embodiments the free space may be air, vacuum, the process gas environment; the constituents of the free space environment are not a limitation of the present invention. In various embodiments boundary 22 may include one or more optical elements, for example a refractive lens, a reflective lens, a mirror, a dichroic mirror, a ball lens, a filter, a dichroic filter or the like. While FIG. 26C shows no gap between the front face or optional window 91 and the top face of optional second base 2614, other embodiments may be configured with a gap in this location. In various embodiments boundary 22 may include a gas, a liquid, or a solid or any combination thereof.

In various embodiments the portion of optional second base 2614 disposed between the proximal end 2635 of probe 108 and front surface 2630 of window 91 may be alumina, diamond, sapphire, quartz, silica, silicon carbide, aluminum nitride, silicon nitride, silicon or the like. In various embodiments the portion of optional second base 2614 disposed between the distal end 2635 of probe 108 and front surface 2630 of window 91 may be transparent or partially transparent or translucent to a wavelength of light utilized in the optical temperature measurement system, for example wavelengths in the range of about 350 microns to about 1100 microns or in the range of about 390 microns to about 800 microns. In various embodiments the portion of optional second base 2641 disposed between the distal end 2635 of probe 108 and the sensing element 14 may have a transmission value of at least 25%, or at least 50%, or at least 75% to a wavelength of light utilized in the optical temperature measurement system, for example wavelengths in the range of about 350 microns to about 1100 microns or in the range of about 390 microns to about 800 microns.

In various embodiments optional second base 2641 may be configured to provide additional protection for the proximal end 2635 of probe 108, for example during multiple process and/or cleaning cycles.

In various embodiments at least a portion of optional window 91 and/or at least a portion of optional second base 2641 may be translucent. In various embodiments a translucent material may be defined as allowing light passage, but the light may be scattered during passage through the material and does not follow Snell's law on a macroscopic level. In contrast a transparent material allows light passage and the light passes through the material with little to no scattering and follows Snell's law. In various embodiments a transparent material may have a uniform or substantially uniform index of refraction, while in various embodiments a translucent material may have a non-uniform index of refraction and/or may include components with different indices of refraction. In various embodiments a translucent material may have a first component and a second component, wherein the index of refraction of the first component is different from the index of refraction of the second component. For example, sapphire and alumina have the same chemical formula Al₂O₃, however in various embodiments alumina is translucent while sapphire is transparent. Alumina is polycrystalline and includes many small crystallites, grain boundaries and pores, each of which is a component that may scatter light and/or may have different indices of refraction.

While FIGS. 26A to 26C include window 91, in other embodiments window 91 may be eliminated. While FIGS. 26A to 26C show at least a portion of the sensing element 14 and a portion of window 91 attached to chamber component 2504 with adhesive 92, in other embodiments adhesive 92 may only be in contact with window 91 or only with the sensing element 14. In various embodiments the sensing element 14 and/or window 91 may be attached to or held in structural element 2604 by other means, for example an epoxy, a ceramic adhesive, a press-fit or mechanical fasteners. In various embodiments window 91 may be alumina, diamond, sapphire, quartz, silica, silicon carbide, aluminum nitride, silicon nitride, silicon or the like.

In various embodiments optical pathway 106 may include an optical fiber, an optical waveguide, an optical fiber bundle or the like.

In various embodiments structural element 2604 may include a portion of an edge ring, or a portion of a shower head or a portion of a chamber wall or a portion of a support structure. In various embodiments structural element 2604 may include glass, aluminum, alumina, diamond, sapphire, quartz, silica, silicon carbide, aluminum nitride, silicon nitride, silicon or the like. However, this is not a limitation and in other embodiments structural element 2504 may include other portions or components in the semiconductor process chamber and/or be made of other materials.

In various embodiments optional second base 2614 may include a portion of an edge ring or a portion of a shower head or a portion of a chamber wall. include glass, aluminum, alumina, diamond, sapphire, quartz, silica, silicon carbide, aluminum nitride, silicon nitride, silicon or the like. However, this is not a limitation and in other embodiments structural element 2504 may include other portions or components in the semiconductor process chamber and/or be made of other materials.

In various embodiments optional first base 2610 may include a portion of an edge ring or a portion of a shower head or a portion of a chamber wall. include glass, aluminum, alumina, diamond, sapphire, quartz, silica, silicon carbide, aluminum nitride, silicon nitride, silicon or the like. However, this is not a limitation and in other embodiments optional first base 2610 may include other portions or components in the semiconductor process chamber and/or be made of other materials.

While FIGS. 26A-26C show implementations of the sensor system in generic chamber structural elements, FIG. 26D shows an implementation of the sensor system in a shower head. FIG. 26D shows an exemplary cross section schematic of a portion of shower head 2560 including a portion of shower head enclosure 2562 enclosing interior volume 2568 and into which is inserted a portion of probe 108, a portion of gas diffuser 2564, gas outlets 2566, remote sensing component 2670 including the sensing element 14 and optional window 91, which may be adhered to at least a portion of sensing element 14 and/or to at least a portion of gas diffuser 2564, and boundary 22.

Referring to FIG. 26D, in various embodiments boundary 22 is disposed between the proximal end 2635 of probe 108 and the front face 2637 of the sensing element 14. Boundary 22 is shown in dashed lines to illustrate that boundary 22 can take the form of a physical boundary such as an optically transparent “window” or passage (for example optional window 91), and/or may represent a gap between the proximal end 2635 of probe 108 and the front face 2637 of the sensing element 14 and/or any structural element(s) (not shown in FIG. 26A for clarity) that contain or support them.

Referring to FIG. 26D, remote sensor component 2670 is located in or on and is in thermal communication with a portion of gas diffuser 2564 such that this example embodiment is configured to measure the temperature of a portion of the gas diffuser 2564. However, this is not a limitation and in other embodiments remote sensor component 2670 may be located and configured to be in thermal communication with other parts of the shower head to measure the respective temperature at those locations. For example, a remote sensor component 2670 could be located in shower head enclosure 2652.

In various embodiments probe 108 may be in part sealed to a structural element or chamber component. Referring to FIG. 26D, O-ring 2690 makes a seal between a portion of probe 108 and a portion of gas diffuser 2564. While FIG. 26D shows an O-ring seal, this is not a limitation and in other embodiments other forms of seals may be used, for example a metal seal or adhesive.

FIG. 26E shows a variation of the system discussed with reference to FIG. 26D, in which probe 108 and remote sensor component 2670 are located at the edge or periphery of shower head 2560. In various embodiments the presence of at least portion of probe 108 and/or at least a portion of remote sensor component 2670 in the interior 2568 of chamber 2560 may modify or adversely affect the gas flow out of gas outlets 2566, for example resulting in a non-uniform distribution of gas across the wafer. Positioning probe 108 and remote sensor component 2670 at the periphery of the interior of shower head 2560 may result in less disruption of the gas distribution or may eliminate the disruption of the gas distribution.

FIG. 26F shows a variation of the systems discussed with reference to FIGS. 26D and 26E, in which probe 108 is located outside of showerhead 2562 and remote sensor component 2670 is located in the wall or enclosure 2562 of showerhead 2560.

Removing all portions of probe 108 and remote sensor component 2670 eliminates any disruption of uniform gas flow in shower head 2560. The system shown in FIG. 26F also includes optional optical element 2690. In various embodiments optical element 2690 may be configured to focus or partially focus a source beam from probe 108 onto the sensing element 14 and/or to focus or partially focus a return beam from the sensing element 14 to probe 108. In various embodiments optical element 2690 may be configured to improve the optical coupling between the sensing element 14 and probe 108.

While FIGS. 26D-26F shows an embodiment of the sensor system configured to measure the temperature in a shower head, this is not a limitation and in other embodiments the sensor system may be configured to measure the temperature in other chamber components, for example an edge ring, a chamber wall, an electrostatic chuck or the like. The specific chamber component is not a limitation of the invention.

In various embodiments chamber component 2604, first base 2610 and second base 2614 may include silicon, polysilicon, silicon carbide, aluminum nitride, sapphire, alumina, quartz, silica, carbon or the like.

FIGS. 27A-27G show various example embodiments of remote sensor component 2670. FIG. 27A shows a cross-section schematic of the remote sensor component 2670 of FIG. 27B through cut line A-A in which a sensing element 2720 is a disc having a diameter 2726 and a thickness 2722.

FIG. 27A also shows an optional window 2710 which is a disc having a diameter 2716, a thickness 2712, a first surface 2718, and a second surface 2719. In various embodiments, the sensing element 2720 is attached to the window 2710 by an adhesive 2730. In various embodiments, the sensing element diameter 2726 may be equal to or less than window diameter 2716. In various embodiments, the difference between the diameter 2726 of sensing element 2720 and the diameter 2716 of the window 2710, identified in FIG. 27A as two times that of a dimension 2724, may be adjusted to optimize mounting in a chamber component or a structural element, as described herein.

In various embodiments, the diameter 2726 of the sensing element 2720 may be in the range of about 1 mm to about 10 mm or in the range of about 2 mm to about 5 mm. In various embodiments, the diameter 2716 of the window 2710 may be in the range of about 1 mm to about 15 mm or in the range of about 3 mm to about 7 mm. In various embodiments, the dimension 2724 may be less than about 5 mm, or less than about 3 mm or less than about 1 mm or may be substantially zero.

In various embodiments, the thickness 2722 of the sensing element 2720 may be in the range of about 50 microns to about 12,000 microns or in the range of about 100 microns to about 700 microns or in the range of about 150 microns to about 500 microns. In various embodiments the thickness 2712 of window 2710 may be in the range of about 0.025 mm to about 3 mm or in the range of about 0.2 mm to about 1.5 mm.

In various embodiments, at least a portion of the adhesive 2730 and at least a portion of the window 2710 may be transparent, partially transparent, or translucent to a wavelength of light utilized in the optical temperature measurement system, (e.g., wavelengths in the range of about 350 microns to about 1100 microns or in the range of about 390 microns to about 800 microns. In various embodiments, at least a portion of the adhesive 2730 and at least a portion of the window 2710 may have a transmission value of at least 25%, or at least 50%, or at least 75% to a wavelength of light utilized in the optical temperature measurement system, (e.g., wavelengths in the range of about 350 microns to about 1100 microns or in the range of about 390 microns to about 800 microns).

FIG. 27C shows a cross-section schematic of the remote sensor component 2670 of FIG. 27D through cut line B-B in which the sensing element 2720 has a square shape having a diagonal length 2726 and a thickness 2722. FIG. 27D also shows an optional window 2710 which is a disc having a diameter 2716 and a thickness 2712 which is attached to the sensing element 2720 by adhesive 2730. In various embodiments, the sensing element diagonal length 2726 may be equal to or less than the window diameter 2716. In various embodiments, the difference between the diagonal length 2726 of the sensing element 2720 and the diameter 2716 of the window 2710, identified in FIG. 27A as a multiple of two times the gap 2724, may be adjusted to optimize mounting in a chamber component, as described herein.

While FIGS. 27B and 27D show sensing element 2720 as having a circle and a square shape respectively, this is not a limitation and in other embodiments sensing element 2720 may have any shape. While FIGS. 27B and 27D show the window 2710 as having a circle shape, in other embodiments the window 2710 may have any shape.

While FIGS. 27A and 27C show sensing element 2720 attached to the window 2710 with the adhesive 2730, in other embodiments the sensing element 2720 may be attached directly to the window 2710 without an additional adhesive, as shown in FIG. 27E. In various embodiments, the sensor element 2720 may be attached to the window 2710 using any means, (e.g., by dispensing the sensing element 2720 onto the window 2710, thermal bonding, anodic bonding or the like).

FIGS. 27F and 27G show example embodiments of a remote sensor component 2670 in which a recess is formed in the window 2710, into which is disposed the sensing element 2720. In the embodiment of FIG. 27F, the sensing element 2720 may be manufactured separately from the window 2710 and subsequently disposed at least partially into the recess in the window 2720, where the sensing element 2720 is attached to the window 2710 with an adhesive 2730. In the embodiment shown in FIG. 27G, the sensing element 2720 may be disposed in the window 2710 without using any adhesive 2730 (as shown in FIG. 27F), by dispensing, press-fit, or the like.

In various embodiments, the diameter 2726 of the sensing element 2720 may be in the range of about 1 mm to about 10 mm or in the range of about 2 mm to about 5 mm. In various embodiments, the diameter 2716 of the window 2710 may be in the range of about 1 mm to about 15 mm or in the range of about 3 mm to about 7 mm. In various embodiments, the gap 2725 may be in the range of about 0.1 mm to about 5 mm or in the range of about 0.25 mm to about 2 mm or in the range of about 0.5 mm to about 1 mm.

In various embodiments, the thickness 2722 of the sensing element 2720 may be in the range of about 50 microns to about 12,000 microns or in the range of about 100 microns to about 700 microns or in the range of about 150 microns to about 500 microns. In various embodiments, the thickness 2712 of the window 2710 may be in the range of about 0.05 mm to about 3 mm or in the range of about 0.3 mm to about 1.5 mm. In various embodiments, the gap 2780 may be less than about 2 mm, or less than about 1 mm or less than about 0.5 mm or less than about 0.1 mm.

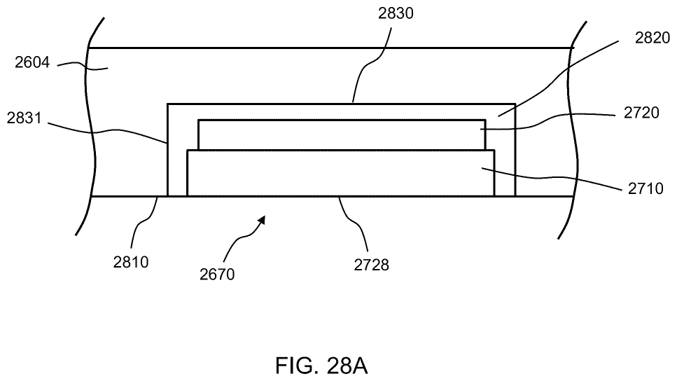

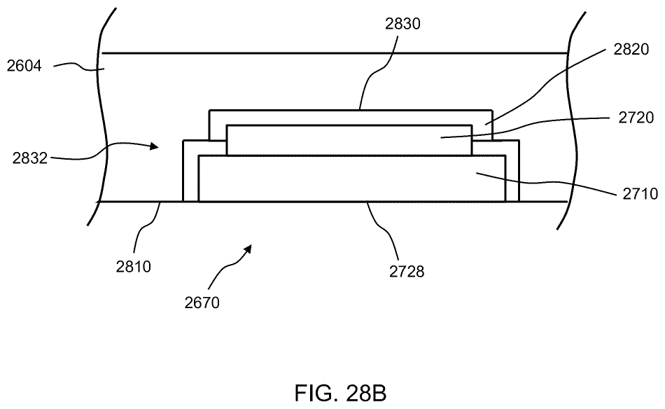

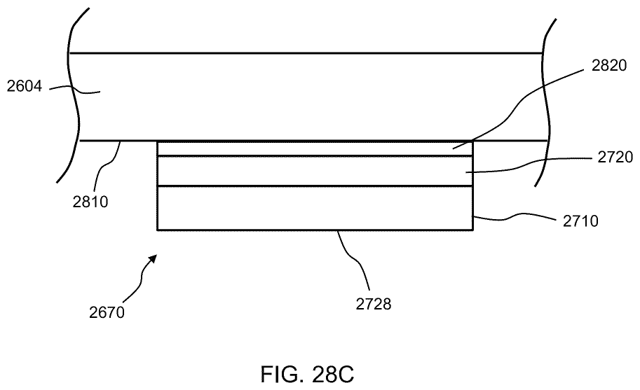

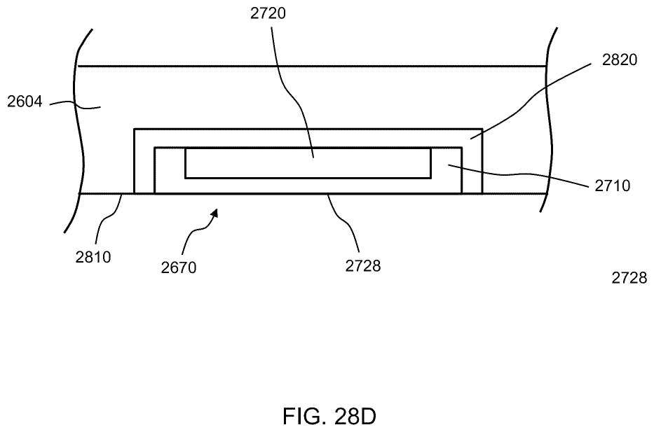

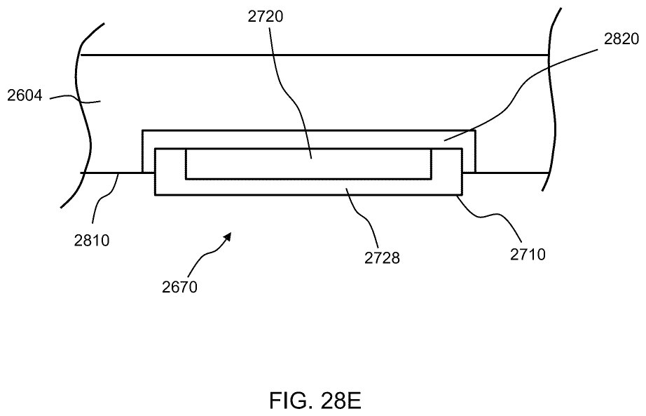

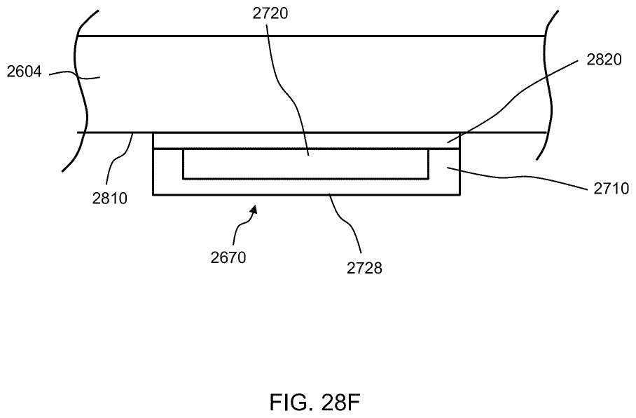

FIGS. 28A-28E show example embodiments for configuring the remote sensor component 2670 into a portion of a chamber component or a structural element. The embodiments in FIGS. 28A-28C include a remote sensing component 2670 as described above in reference to FIGS. 27A-27E, without a recess in the window 2710, while the embodiments in FIGS. 28D-28F include a remote sensing component 2670 as described in reference to FIGS. 27F-27G, having a recess in the window 2710.

Referring to the example embodiments shown in FIGS. 28A and 28B, the remote sensing component 2670 is embedded in a recess 2830 in a chamber component 2604 such that a front face or surface 2728 of a window 2710 is coplanar or substantially coplanar with at least a portion of a surface 2810 of the chamber component 2604. In various embodiments, the adhesive 2820 fills a region between the recess 2830 and the remote sensing component 2670. In various embodiments, the recess 2830 may have straight sidewalls 2831, while in other embodiments the sidewalls may be shaped, for example, to minimize the amount of adhesive required to attach the remote sensing component 2670 to the chamber component 2604. FIG. 28B shows an example embodiment in which a recess 2830 has a stepped sidewall 2832. In various embodiments, the embedding of the remote sensor component 2670 may improve the thermal communication between at least a portion of the chamber component 2604 and the remote sensor component 2670. Those skilled in the art will appreciate that that the sidewall 2832 may have any shape.

In various embodiments, the remote sensor component 2670 may not be fully embedded in the chamber component 2604, but rather may be attached on the surface 2810 of the chamber component 2504 as shown in FIG. 28C, with an adhesive 2820.

FIG. 28D shows an example embodiment of the remote sensor component 2670, fully embedded in at least a portion of the chamber component 2604, so that the surface 2728 of the remote sensor component 2670 is coplanar or substantially coplanar with at least a portion of the surface 2810 of the structural element 2604.

FIG. 28E shows an example embodiment of remote sensor component 2670, partially embedded in at least a portion of chamber component 2604, such that the surface 2728 of the remote sensor component 2670 is proud of at least a portion of surface 2810 of the structural element 2604.

FIG. 28F shows an example embodiment of remote sensor component 2670, mounted on the surface 2810 of the chamber component 2604.

While FIGS. 28A-28E show embodiments in which the remote sensor element 2670 is attached to a structural element or a chamber component using adhesive, in other embodiments, this attachment may be done using other means (e.g., mechanical attachment, solder, press-fit, fasteners, or the like).

In various embodiments, the adhesive 2820 or other means to attach the remote sensor element 2670 to the structural element 2604 may have a relatively high thermal conductivity, to reduce the temperature difference between the structural element 2604 and the sensing element 2720, to result in a measured value that is closer to the actual temperature of the structural element 2604. In various embodiments, the thermal conductivity of the attachment means, for example, the adhesive, may be at least 0.5 W/m° C., at least 5 W/m° C., at least 10 W/m° C., at least 50 W/m° C., or at least 100 W/m° C.

In various embodiments, a sensing element, for example the sensing element 14 or 2720, may include a phosphor powder in a binder. In various embodiments, the binder may include epoxy, glass, silica, silicone, or the like. Also, in other embodiments the sensing element 14 may be a ceramic.

Although the above description includes reference to certain specific embodiments, various modifications thereof will be apparent to those skilled in the art. Any examples provided herein are included solely for the purpose of illustration and are not intended to be limiting in any way.

Any drawings provided herein are solely for the purpose of illustrating various aspects of the description and are not intended to be drawn to scale or to be limiting in any way. The scope of the claims appended hereto should not be limited by the preferred embodiments set forth in the above description, but should be given the broadest interpretation consistent with the present specification as a whole. The disclosures of all prior art recited herein are incorporated herein by reference in their entirety.

What is claimed is:

1. A temperature sensor system, comprising:
at least one sensing element configured to be in thermal communication with at least a portion of a structural element of a semiconductor processing chamber, wherein the at least one sensing element is configured to emit at least one return beam in response to a source beam;
a controller including a converter having at least one light source configured to emit at least one source beam and at least one first detector configured to detect at least a portion of the at least one return beam;
at least one optical pathway having a first end and a second end opposite the first end, wherein the first end is spaced apart from the at least one sensing element and where the optical pathway is configured to conduct at least a portion of the at least one source beam from the converter to the at least one sensing element and to conduct at least a portion of the at least one return beam from the at least one sensing element to the at least one first detector; and
at least one boundary at least partially disposed between the first end of the at least one optical pathway and the at least one sensing element, the at least one boundary comprising at least one of a gas, a solid, or a liquid,
wherein:
(i) the at least one boundary is at least partially transparent to at least a portion of the at least one source beam and to at least a portion of the at least one return beam; and
(ii) the at least one controller is configured to calculate a temperature of the sensing element in thermal communication based on at least one characteristic of the at least one return beam.

2. The temperature sensor system of claim 1, wherein the at least one characteristic of the at least one return beam comprises at least one selected from a group of an intensity or amplitude, a change in intensity or amplitude over a time period, an intensity decay rate, a decay time constant, an optical power spectrum, and one or more portions of an optical power spectrum.

3. The temperature sensor system of claim 1, wherein the at least one controller is configured to:
(i) modulate the source beam such that during a portion of a time the source beam is off; and
(ii) calculate a temperature of the sensing element based on at least one characteristic of the at least one return beam detected by the at least one first detector during at least a portion of the time when the source beam is off.

4. The temperature sensor system of claim 1, wherein the at least one portion of the structural element comprises at least a portion of at least one of the group of edge ring, shower head, and chamber wall.

5. The temperature sensor system of claim 1, wherein the at least one boundary has a thickness of at least 0.25 mm.

6. The temperature sensor system of claim 1, wherein the at least one sensing element is spaced apart from the first end of the at least one optical pathway by at least 0.25 mm.

7. The temperature sensor system of claim 1, wherein the at least one boundary comprises at least one selected from the group of sapphire, diamond, glass, alumina, aluminum oxide, silicon carbide, aluminum nitride, vacuum, air, a gas, and a free space optical pathway.

8. The temperature sensor system of claim 1, wherein the at least one boundary comprises a first portion and a second portion, wherein the first portion of the at least one boundary is different from the second portion of the at least one boundary and the first portion of the at least one boundary comprises a free-space optical pathway and the second portion of the at least one boundary comprises a solid, wherein the solid is at least partially transparent to a wavelength of the source beam and is at least partially transparent to a wavelength of the return beam.

9. The temperature sensor system of claim 8, wherein the solid comprises at least one selected from the group of diamond, glass, alumina, aluminum oxide, sapphire, quartz, silica, silicon, silicon carbide, and aluminum nitride.

10. The temperature sensor system of claim 1, wherein the at least one sensing element is disposed at least partially in at least a portion of the at least one portion of a structural element.

11. The temperature sensor system of claim 1, wherein the at least one sensing element is disposed on at least a portion of the at least one portion of a structural element.

12. The temperature sensor system of claim 1, wherein at least a portion of the at least one portion of the structural element comprises a first recess and the at least one sensing element is disposed at least partially within the first recess in the at least one portion of the at least one portion of the structural element.

13. The temperature sensor system of claim 1, wherein the at least one sensing element is attached to at least a portion of the at least one portion of the structural element with at least one selected from the group of a bond, an adhesive, and a press-fit joint.

14. The temperature sensor system of claim 1, wherein the at least one boundary comprises an optical element.

15. The temperature sensor system of claim 14, wherein the at least one optical element comprises at least one lens to focus the beams emitted and received at the first end of the optical pathway.

16. The temperature sensor system of claim 1, wherein the at least one boundary comprises at least one first coating disposed on at least a portion of the at least one sensing element, wherein the at least one first coating is at least partially transparent to a wavelength of the source beam and is at least partially transparent to a wavelength of the return beam.

17. The temperature sensor system of claim 16, further comprising a window disposed between the first end of the optical pathway and the sensing element, wherein the window is at least partially transparent to a wavelength of the source beam and is at least partially transparent to a wavelength of the return beam.

18. The temperature sensor system of claim 17, wherein the window is attached to at least a portion of the at least a portion of the structural element.

19. The temperature sensor system of claim 18, wherein the window is hermetically sealed to at least a portion of the at least one portion of the structural element.

20. The temperature sensor system of claim 17, wherein the window comprises at least one selected from the group of alumina, diamond, glass, sapphire, quartz, silica, silicon carbide, aluminum nitride, aluminum oxide, silicon nitride, and silicon.

21. The temperature sensor system of claim 17, wherein at least a portion of the at least a portion of the structural element comprises a first recess and a second recess, wherein the first recess is disposed within the second recess and the sensing element is disposed at least partially within the first recess and the window is disposed at least partially within the second recess.

22. The temperature sensor system of claim 1, wherein the optical pathway comprises at least one selected from the group of an optical fiber, an optical waveguide, and an optical fiber bundle.

23. The temperature sensor system of claim 1, further comprising a probe having a first end and a second end, the first end opposite the second end, wherein at least a portion of the at least one optical pathway is disposed within the probe and the first end of the probe shaft is spaced apart from the at least one sensing element.
